(19) United States
(12) Patent Application Publication
(10) Pub. No.: US 2025/0089310 A1
(43) Pub. Date: Mar. 13, 2025

(54) THROUGH-GATE STRUCTURE WITH AN AIRGAP SPACER IN A SEMICONDUCTOR DEVICE

(71) Applicant: Intel Corporation, Santa Clara, CA (US)

(72) Inventors: Ting-Hsiang Hung, Beaverton, OR (US); Yang Zhang, Rio Rancho, NM (US); Robin Chao, Portland, OR (US); Guowei Xu, Portland, OR (US); Tao Chu, Portland, OR (US); Chiao-Ti Huang, Portland, OR (US); Feng Zhang, Hillsboro, OR (US); Chia-Ching Lin, Portland, OR (US); Anand Murthy, Portland, OR (US)

(73) Assignee: Intel Corporation, Santa Clara, CA (US)

(21) Appl. No.: 18/466,246

(22) Filed: Sep. 13, 2023

(51) Int. Cl. H01L 29/06; H01L 27/092; H01L 29/423; H01L 29/778; H01L 29/786

(52) U.S. Cl. CPC H10D 62/115; H10D 30/47; H10D 30/6735; H10D 30/6757; H10D 62/118; H10D 84/85

(57) ABSTRACT

Techniques are provided to form semiconductor devices that include through-gate structures (e.g., gate cut structures or conductive via structures) that have an airgap spacer between the structure and the adjacent gate electrode. In an example, a semiconductor device includes a gate structure around or otherwise on a semiconductor region (or channel region) that extends from a first source or drain region to a second source or drain region. A through-gate structure may extend in a third direction through an entire thickness of the gate structure and adjacent to the semiconductor region along the second direction. The through-gate structure may be a dielectric structure (e.g., a gate cut) or a conductive structure (e.g., a via). In either case, an airgap spacer exists between the through-gate structure and the gate structure.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, the formation of certain device structures used to isolate adjacent transistors becomes challenging. Accordingly, there remain a number of non-trivial challenges with respect to forming semiconductor devices.

### BRIEF DESCRIPTION OF THE DRAWINGS

FIGS. 1A and 1B are cross-sectional views of some semiconductor devices that include through-gate structures with airgap spacers, in accordance with an embodiment of the present disclosure.

FIG. 1C is a plan view of the integrated circuit of FIGS. 1A and 1B, in accordance with an embodiment of the present disclosure.

FIGS. 2A and 2B are cross-sectional views that illustrate a stage in an example process for forming semiconductor devices that include through-gate structures with airgap spacers, in accordance with some embodiments of the present disclosure.

FIGS. 3A and 3B are cross-sectional views that illustrate another stage in the example process for forming semiconductor devices that include through-gate structures with airgap spacers, in accordance with some embodiments of the present disclosure.

FIGS. 4A and 4B are cross-sectional views that illustrate another stage in the example process for forming semiconductor devices that include through-gate structures with airgap spacers, in accordance with some embodiments of the present disclosure.

FIGS. 5A and 5B are cross-sectional views that illustrate another stage in the example process for forming semiconductor devices that include through-gate structures with airgap spacers, in accordance with some embodiments of the present disclosure.

FIGS. 6A and 6B are cross-sectional views that illustrate another stage in the example process for forming semiconductor devices that include through-gate structures with airgap spacers, in accordance with some embodiments of the present disclosure.

FIGS. 7A and 7B are cross-sectional views that illustrate another stage in the example process for forming semiconductor devices that include through-gate structures with airgap spacers, in accordance with some embodiments of the present disclosure.

FIGS. 8A and 8B are cross-sectional views that illustrate another stage in the example process for forming semiconductor devices that include through-gate structures with airgap spacers, in accordance with some embodiments of the present disclosure.

FIGS. 9A and 9B are cross-sectional views that illustrate another stage in the example process for forming semiconductor devices that include through-gate structures with airgap spacers, in accordance with some embodiments of the present disclosure.

FIGS. 10A and 10B are cross-sectional views that illustrate another stage in the example process for forming semiconductor devices that include through-gate structures with airgap spacers, in accordance with some embodiments of the present disclosure.

FIGS. 11A and 11B are cross-sectional views that illustrate another stage in the example process for forming semiconductor devices that include through-gate structures with airgap spacers, in accordance with some embodiments of the present disclosure.

FIGS. 12A and 12B are cross-sectional views that illustrate another stage in the example process for forming semiconductor devices that include through-gate structures with airgap spacers, in accordance with some embodiments of the present disclosure.

FIGS. 13A and 13B are cross-sectional views that illustrate another stage in the example process for forming semiconductor devices that include through-gate structures with airgap spacers, in accordance with some embodiments of the present disclosure.

FIGS. 14A and 14B are cross-sectional views that illustrate another stage in the example process for forming semiconductor devices that include through-gate structures with airgap spacers, in accordance with some embodiments of the present disclosure.

FIGS. 15A and 15B are cross-sectional views that illustrate another stage in the example process for forming semiconductor devices that include through-gate structures with airgap spacers, in accordance with some embodiments of the present disclosure.

FIGS. 16A and 16B are cross-sectional views that illustrate another stage in the example process for forming semiconductor devices that include through-gate structures with airgap spacers, in accordance with some embodiments of the present disclosure.

FIG. 17 illustrates an example plan view across an integrated circuit, in accordance with some embodiments of the present disclosure.

FIG. 18 illustrates a cross-sectional view of a chip package containing one or more semiconductor dies, in accordance with some embodiments of the present disclosure.

FIG. 19 is a flowchart of a fabrication process for semiconductor devices that include through-gate structures with airgap spacers, in accordance with an embodiment of the present disclosure.

FIG. 20 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include through-gate structures (e.g., gate cut structures or conductive via structures) that have an airgap spacer between the structure and the adjacent gate electrode. The techniques can be used in any number of integrated circuit applications and are particularly useful with respect to device layer transistors, such as finFETs or gate-all-around transistors (e.g., ribbonFETs and nanowire FETs). In an example, a semiconductor device includes a gate structure around or otherwise on a semiconductor region (or channel region) that extends from a first source or drain region to a second source or drain region. The semiconductor regions can be, for example, fins of semiconductor material or one or more nanowires or nanoribbons or nanosheets of semiconductor material that extend between the first and second source or drain regions along a first direction while the gate structure extends over the semiconductor regions along a second direction. A structure may extend in a third direction through an entire thickness of the gate structure and adjacent to the semiconductor region along the second direction. The structure may be a dielectric structure (e.g., a gate cut) or a conductive structure (e.g., a via). In either case, an airgap spacer exists between the structure and the gate structure. The presence of the airgap spacer provides a region with a very low dielectric constant (e.g., around 1.0) between the structure and the adjacent gate structure, thus reducing the parasitic capacitance in the device. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Example through-gate structures like gate cuts or vias are used in integrated circuit design to isolate gate structures from one another and (in the case of vias) provide a signal or power routing path to backside interconnects. Such gate cuts may be relatively thin and are thus filled with a robust high-k dielectric material (e.g., a material with a dielectric constant of 6.5 or greater, such as silicon nitride). Similarly, via structures may have a dielectric liner along its edges that includes a high-k dielectric material. But the use of such high-k materials can lead to high parasitic capacitance between the conductive gate electrode on either side of the gate cut or via. Using a low-k dielectric material instead can help to reduce such parasitic capacitance. However, low-k materials usually include an oxygen component, and deposition of oxygen-containing dielectric materials implicates oxidation risk of the underlying material(s). Also, deposition of oxygen-containing dielectric materials includes ion flux. Such factors can cause shifting in electrical properties of the underlying material(s). Also, oxygen-rich low-k dielectric materials may not be robust enough to withstand erosion caused by, for example, downstream processing and planarization.

Thus, and in accordance with an embodiment of the present disclosure, an integrated circuit is disclosed that includes one or more through-gate structures (gate cut structures or conductive via structures) having an airgap spacer between the through-gate structure and the adjacent gate electrode. Additionally, the through-gate structures may extend in a first direction to be adjacent to source or drain regions and the airgap spacer also exists between the through-gate structure and the adjacent source or drain regions. According to some embodiments, a deep recess is formed through at least an entire thickness of the gate structure and adjacent to a semiconductor region that extends in the first direction between source or drain regions. The deep recess may also extend through at least a portion of an entire thickness of a dielectric layer beneath the gate structure. A sacrificial layer may be formed along walls of the deep recess and the through-gate structure is then formed on the sacrificial layer. Following the formation of the semiconductor devices and any back-end-of-the-line (BEOL) processes, the substrate may be removed from the backside, exposing a bottom surface of the through-gate structure and the sacrificial layer along the edges of the through-gate structure. The sacrificial layer may then be removed from the backside, leaving behind an airgap spacer having substantially the same width as the sacrificial layer. The sacrificial layer may be aluminum oxide and may have a thickness of less than 10 nm.

According to an embodiment, an integrated circuit includes a semiconductor device having a semiconductor region extending in a first direction from a source or drain region and a gate structure extending in a second direction over the semiconductor region, a dielectric layer beneath the gate structure, and a structure spaced from the semiconductor region in the second direction and extending in a third direction along an entire thickness of the gate structure and along an entire thickness of the dielectric layer. An airgap exists between the structure and the gate structure and between the structure and the dielectric layer.

According to another embodiment, an integrated circuit includes a semiconductor device having a semiconductor region extending in a first direction from a source or drain region, and a gate structure extending in a second direction over the semiconductor region, a first dielectric layer beneath the gate structure, a conductive structure spaced from the semiconductor region in the second direction and extending in a third direction along an entire thickness of the gate structure and along an entire thickness of the dielectric layer, and a second dielectric layer over the gate structure and on a top surface of the conductive structure. An airgap exists between the conductive structure and the gate structure and between the conductive structure and the dielectric layer.

According to another embodiment, a method of forming an integrated circuit includes forming a fin comprising semiconductor material, the fin extending above a substrate and extending in a first direction; forming a dielectric layer adjacent to a subfin portion of the fin; forming source or drain regions at opposite ends of the fin; forming a gate structure on the dielectric layer and over the semiconductor material and extending in a second direction; forming a recess through an entire thickness of the gate structure and through an entire thickness of the dielectric layer; forming a sacrificial layer along sidewalls and a bottom surface of the recess; forming a conductive material on the sacrificial layer within the recess; removing the substrate from the backside of the integrated circuit, wherein the removing exposes a bottom surface of the conductive material; and removing the sacrificial layer from the backside to form an airgap between the conductive material and the gate structure and between the conductive material and the dielectric layer.

The techniques can be used with any type of non-planar transistors, including finFETs (sometimes called tri-gate transistors), nanowire and nanoribbon transistors (sometimes called gate-all-around transistors), or forksheet transistors, to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of airgaps along the edges of through-gate structures (e.g., gate cuts or vias). The airgaps may extend along an entire interface between a given through-gate structure and the adjacent gate electrode. In some embodiments, airgaps are also present between the through-gate structures and adjacent source or drain regions along a given source/drain trench.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

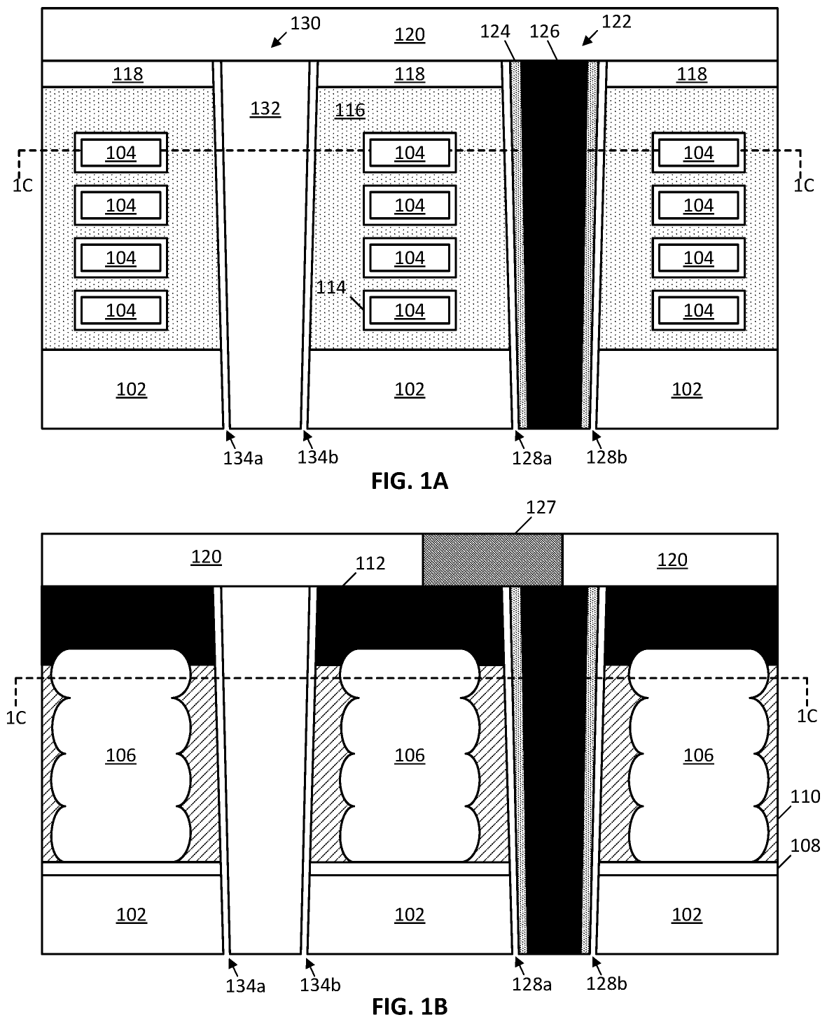

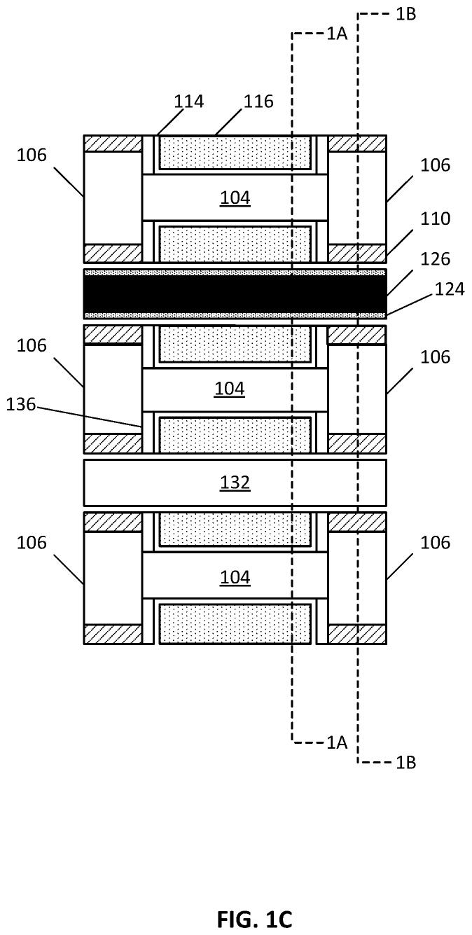

FIG. 1A is a cross-sectional view taken across the gate trench of three example semiconductor devices, according to an embodiment of the present disclosure. FIG. 1B is another cross-sectional view taken across the source/drain trench or diffusion region and contact trench adjacent to the gate trench either into or out of the page of FIG. 1A. FIG. 1C is a top-down cross-section view of the adjacent semiconductor devices taken across the dashed line 1C-1C depicted in both FIG. 1A and FIG. 1B. FIG. 1A illustrates the cross-section taken across the dashed line 1A-1A depicted in FIG. 1C, and FIG. 1B illustrates the cross-section taken across the dashed line 1B-1B depicted in FIG. 1C.

Each of the semiconductor devices may be, for example, non-planar metal oxide semiconductor (MOS) transistors, such as tri-gate (e.g., finFET) or gate-all-around (GAA) transistors, although other transistor topologies and types could also benefit from the techniques provided herein. The illustrated example embodiments use the GAA structure. The various illustrated semiconductor devices represent a portion of an integrated circuit that may contain any number of similar semiconductor devices.

As can be seen, the semiconductor devices may be formed over a dielectric base layer 102. In some embodiments, a lower portion of (or all of) the substrate beneath dielectric base layer 102 is removed and replaced with one or more backside interconnect layers to form, for example, backside signal and power routing, during a backside process. Dielectric base layer 102 may represent any number of deposited dielectric materials, and may include different dielectric materials such as silicon dioxide, silicon oxynitride, silicon nitride, and/or silicon oxycarbonitride.

Each of the semiconductor devices includes one or more corresponding nanoribbons 104 that extend parallel to one another along a first direction between corresponding source or drain regions as seen more clearly in FIG. 1C. Accordingly, each set of nanoribbons 104 extends in the first direction between a corresponding set of source or drain regions 106. Nanoribbons 104 are one example of semiconductor regions or semiconductor bodies that extend between source or drain regions 106. According to some embodiments, nanoribbons 104 (or other semiconductor bodies) extend between source or drain regions 106 in the first direction to provide an active region (sometimes called channel region) for a transistor (e.g., the semiconductor region beneath the gate). It should be understood that the source or drain regions 106 illustrated in the cross-section of FIG. 1B are only along one side of nanoribbons 104 (e.g., out of the page of FIG. 1A) and that similar source or drain regions may be present along the opposite side of nanoribbons 104, as shown in FIG. 1C.

The term nanoribbon may also encompass other similar shapes such as nanowires or nanosheets. The semiconductor material of nanoribbons 104 may be formed from a semiconductor substrate. In some embodiments, the semiconductor devices may each include semiconductor regions in the shape of fins that can be, for example, native to the substrate (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitate forming of the illustrated nanoribbons 104 during a gate forming process where one type of the alternating layers is selectively etched away so as to liberate the other type of alternating layers within the channel region, so that a gate-all-around (GAA) process can then be carried out. Again, the alternating layers can be blanket deposited and then etched into fins or deposited into fin-shaped trenches.

According to some embodiments, the source or drain regions are epitaxial regions that are provided using an etch-and-replace process. In other embodiments the source or drain regions could be, for example, implantation-doped native portions of the semiconductor fins or substrate. Any semiconductor materials suitable for source and drain regions can be used (e.g., group IV and group III-V semiconductor materials). The composition and doping of the source or drain regions may be the same or different, depending on the polarity of the transistors. In an example, for instance, one transistor is a p-type MOS (PMOS) transistor, and the other transistor is an n-type MOS (NMOS) transistor. As such, source or drain region 106 may have a different dopant type (n or p) compared to any other source or drain region 106 along a given source/drain trench. Any number of source or drain configurations and materials can be used.

According to some embodiments, a lower dielectric layer 108 exists beneath source or drain regions 106. Lower dielectric layer 108 can include any suitable dielectric material, such as silicon dioxide or silicon nitride or silicon oxynitride and may be provided to isolate source or drain regions 106 from other underlying structures. According to some embodiments, another dielectric fill 110 is provided around and/or over portions of source or drain regions 106 along the source/drain trench after epitaxial formation of the source/drain regions is complete. Dielectric fill 110 may be any suitable dielectric material, although in some embodiments, dielectric fill 110 includes the same dielectric material within dielectric base layer 102 or lower dielectric layer 108. In one example, each of dielectric fill 110, lower dielectric layer 108, and dielectric base layer 102 includes silicon dioxide. According to some embodiments, any number of conductive contacts 112 may be formed on corresponding source or drain regions 106. According to some embodiments, conductive contacts 112 may be any suitably conductive material such as tungsten (W). Other conductive materials may include copper (Cu), ruthenium (Ru), cobalt (Co), titanium (Ti), molybdenum (Mo), or any alloys thereof. Conductive contacts 112 may be formed directly on a top surface of source or drain regions 106 and may extend along portions of the sides of source or drain regions 106.

According to some embodiments, a gate structure extends over nanoribbons 104 of each semiconductor device along a second direction across the page of FIG. 1A. The gate structure includes a gate dielectric 114 and a gate electrode 116. Gate dielectric 114 represents any number of dielectric layers present between nanoribbons 104 and gate electrode 116. Gate dielectric 114 may also be present on the surfaces of other structures within the gate trench, such as on a to surface of dielectric base layer 102. Gate dielectric 114 may include any suitable gate dielectric material(s). In some embodiments, gate dielectric 114 includes a layer of native oxide material (e.g., silicon dioxide) on the nanoribbons or other semiconductor regions making up the channel region of the devices, and a layer of high-k dielectric material (e.g., hafnium oxide) on the native oxide.

Gate electrode 116 may represent any number of conductive layers, such as any metal, metal alloy, or doped polysilicon layers. In some embodiments, gate electrode 116 includes one or more workfunction metals around nanoribbons 104. In some embodiments, one of the semiconductor devices is a p-channel device that includes a workfunction metal having titanium around its nanoribbons and another semiconductor device is an n-channel device that includes a workfunction metal having tungsten around its nanoribbons. Gate electrode 116 may also include a fill metal or other conductive material around the workfunction metals to provide the whole gate electrode structure. In some embodiments, a gate cap 118 may be provided on a top surface of gate electrode 116 within the gate trench. Gate cap 118 may be any suitable dielectric material, such as silicon oxynitride, silicon nitride, or silicon oxycarbonitride.

According to some embodiments, a first interconnect layer above the semiconductor devices includes a dielectric interconnect layer 120. Dielectric interconnect layer 120 may have any number of conductive vias or conductive layers present within it. Dielectric interconnect layer 120 may include any suitable dielectric material, such as silicon dioxide.

According to some embodiments, various through-gate structures are present that pass across the gate trench in the first direction and through an entire thickness of the gate structure in a third direction. For example, a conductive via structure 122 may extend along the first direction through the gate structure and across the source/drain trench to pass adjacent to source or drain regions 106, as illustrated in FIG. 1B. Conductive via structure may include any number of conductive materials. For example, conductive via structure 122 can include a conductive liner 124 and a conductive fill 126 on conductive liner 124. Conductive liner 124 may include titanium nitride or tantalum nitride. Conductive fill 126 may include any suitable conductive material, such as tungsten, ruthenium, molybdenum, or cobalt, to name a few examples. In some embodiments, a conductive interconnect layer 127 as part of a first interconnect layer above the semiconductor devices contacts a top surface of conductive via structure 122. Conductive interconnect layer 127 may also extend across the second direction to contact a top surface of one or more conductive contacts 112. Conductive interconnect layer 127 may include any suitable conductive material, such as tungsten, ruthenium, molybdenum, copper, or cobalt, to name a few examples. According to some embodiments, airgaps 128a-128b exist between the sidewalls of conductive via structure 122 and any other structures adjacent to conductive via structure 122. Accordingly, airgaps 128a-128b exist between conductive via structure 122 and gate electrode 116 and between conductive via structure 122 and dielectric base layer 102. Airgaps 128a-128b may have a width of less than 10 nm and may extend along an entire height of each sidewall of conductive via structure 122. As seen in FIG. 1B, airgaps 128a-128b may also be between conductive via structure 122 and source or drain regions 106 along the source/drain trench. According to some embodiments, dielectric interconnect layer 120 bridges across airgap 128b and portions of airgap 128a and conductive interconnect layer 127 bridges across a portion of airgap 128b.

Another example through-gate structure includes a gate cut 130. According to some embodiments, gate cut 130 may also extend along the first direction through the gate structure and across the source/drain trench to pass adjacent to source or drain regions 106, as illustrated in FIG. 1B. Gate cut 130 may include any number of dielectric materials. In one example, gate cut 130 includes a dielectric fill 132 having silicon dioxide, silicon nitride, or silicon oxynitride. According to some embodiments, airgaps 134a-134b exist between the sidewalls of gate cut 130 and any other structures adjacent to gate cut 130. Accordingly, airgaps 134a-134b exist between gate cut 130 and gate electrode 116 and between gate cut 130 and dielectric base layer 102. Airgaps 134a-134b may have a width of less than 10 nm and may extend along an entire height of each sidewall of gate cut 130. As seen in FIG. 1B, airgaps 134a-134b may also be between gate cut 130 and source or drain regions 106 along the source/drain trench. Airgaps 134a-134b may be substantially the same in terms of thickness as airgaps 128a-128b. According to some embodiments, dielectric interconnect layer 120 bridges across both airgaps 128a and 128b.

In some embodiments, the transistor structures are very densely packed such that there is little space between adjacent source or drain regions 106 along the second direction. In such examples, any of airgaps 128a-128b or airgaps 134a-134b may directly abut or expose a portion of the adjacent source or drain regions 106.

FIG. 1C illustrates the plan view of the integrated circuit showing how nanoribbons 104 extend between corresponding source or drain regions 106. According to some embodiments, spacer structures 136 extend along the sides of the gate trench and isolate the gate trench from the source/drain trench (including epi or doped regions and their respective contacts). Spacer structures 136 may include any suitable dielectric material, such as silicon nitride. The nanoribbons 104 (or other channel body) extend through spacer structures 136 to contact respective source or drain regions 106.

### Fabrication Methodology

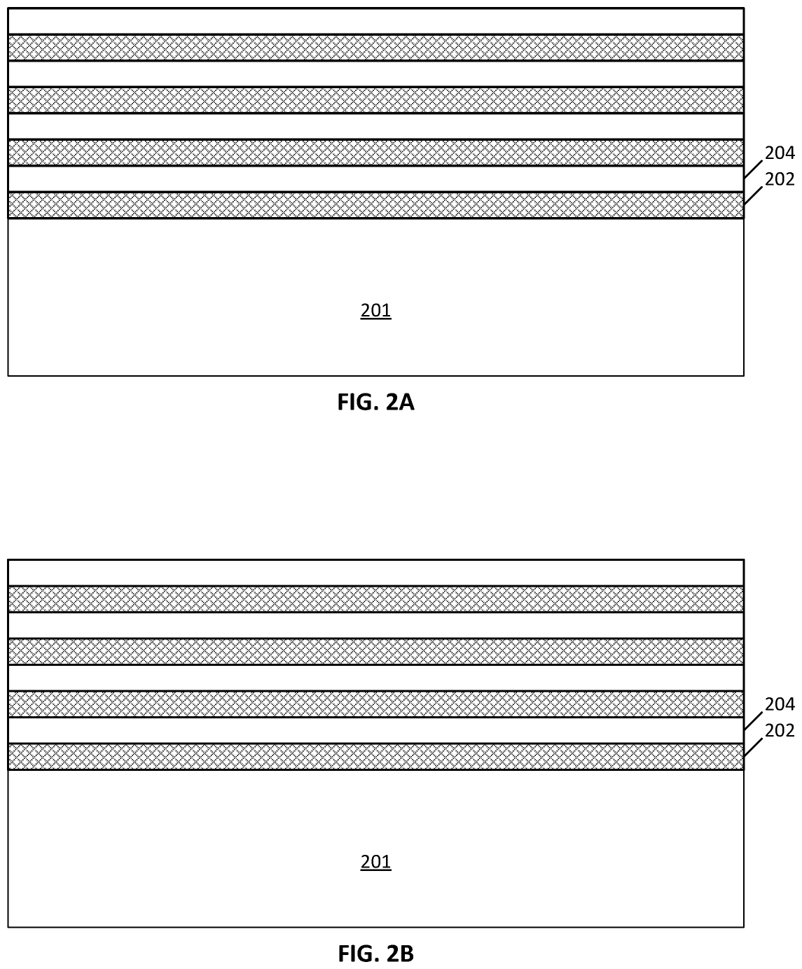

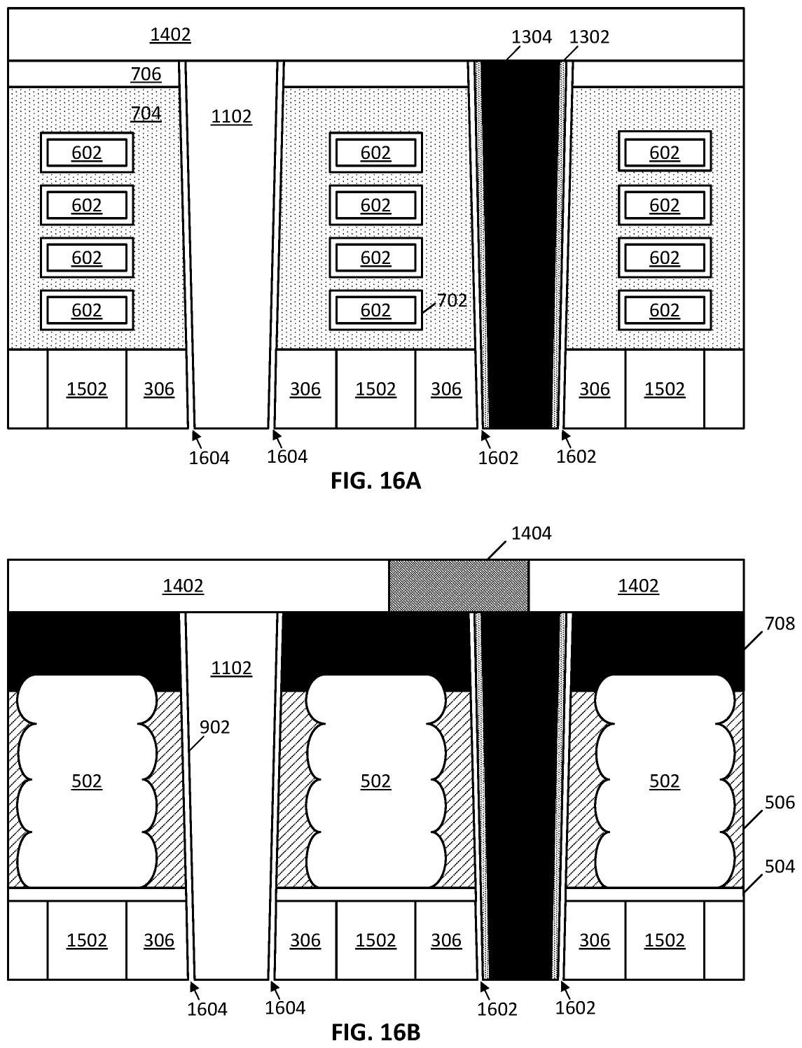

FIGS. 2A-16A and 2B-16B are cross-sectional views that collectively illustrate an example process for forming an integrated circuit that include through-gate structures with airgap spacers, in accordance with an embodiment of the present disclosure. FIGS. 2A-16A represent cross-sectional views taken across a gate trench of the integrated circuit, while FIGS. 2B-16B represent cross-sectional views taken across the source/drain trench adjacent to the gate trench along the same direction. Each figure shows an example structure that results from the process flow up to that point in time, so the depicted structure evolves as the process flow continues, culminating in the structure shown in FIGS. 16A and 16B, which is similar to the structure shown in FIGS. 1A and 1B, respectively. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. Figures sharing the same number (e.g., FIGS. 2A and 2B) illustrate different views of the structure at the same point in time during the process flow. Although the fabrication of two different through-gate structures are illustrated in the aforementioned figures, it should be understood that any number of similar through-gate structures can be fabricated across the integrated circuit using the same processes discussed herein.

FIGS. 2A and 2B illustrate parallel cross-sectional views taken through a stack of alternating semiconductor layers on semiconductor substrate 201. FIG. 2A is taken across a portion of the stack that will eventually become a gate trench while FIG. 2B is taken across a portion of the stack that will eventually become a source/drain trench adjacent and parallel to the gate trench. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201.

Substrate 201 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm), and the thickness of each of semiconductor layers 204 may be about the same as the thickness of each sacrificial layer 202 (e.g., about 5-20 nm). Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

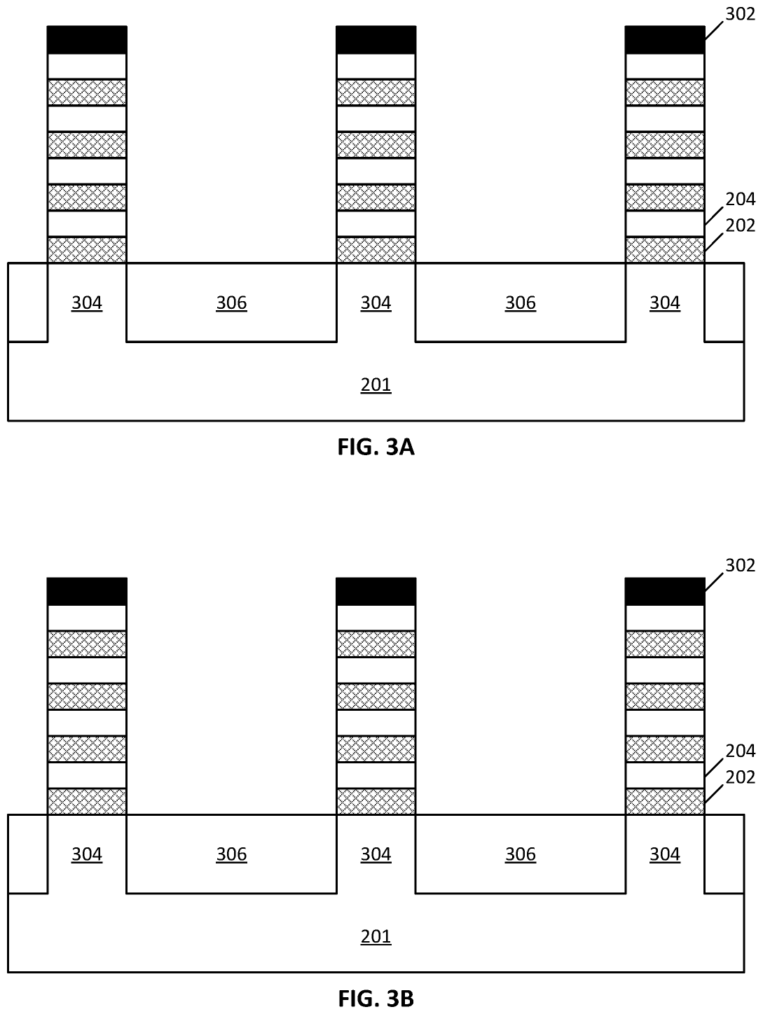

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. The rows of fins extend lengthwise in a first direction (e.g., into and out of the page of each cross-section view).

According to some embodiments, an anisotropic etching process through the layer stack continues into at least a portion of substrate 201, where the unetched portions of substrate 201 beneath the fins form subfin regions 304. The etched portions of substrate 201 may be filled with a dielectric fill 306 that acts as shallow trench isolation (STI) between adjacent fins. Dielectric fill 306 may be any suitable dielectric material such as silicon dioxide, and may be recessed to a desired depth as shown (in this example case, down to around the upper surface of subfin regions 304), so as to define the active portion of the fins that will be covered by a gate structure. In some embodiments, dielectric fill 306 is recessed below the top surface of subfin regions 304.

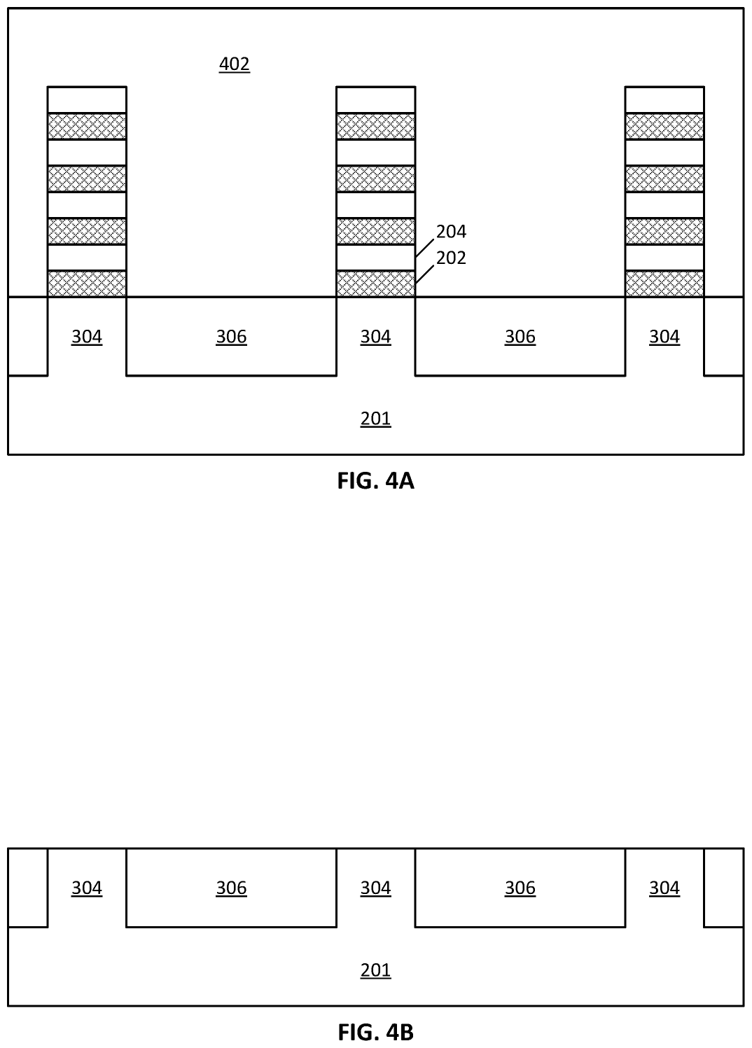

FIGS. 4A and 4B depict the cross-section views of the structure shown in FIGS. 3A and 3B, respectively, following the formation of a sacrificial gate 402 extending across the fins in a second direction different from the first direction, according to some embodiments. Sacrificial gate 402 may extend across the fins in a second direction that is orthogonal to the first direction. According to some embodiments, the sacrificial gate material is formed in parallel strips across the integrated circuit and removed in all areas not protected by a gate masking layer. Sacrificial gate 402 may be any suitable material that can be selectively removed without damaging the semiconductor material of the fins. In some examples, sacrificial gate 402 includes polysilicon.

As seen in the cross-section views, sacrificial gate 402 extends across the fins along the gate trench cross-section of FIG. 4A but is not present along the source/drain trench cross-section of FIG. 4B. Accordingly, sacrificial gate 402 (along with any gate spacers formed on the sidewalls of sacrificial gate 402) protect the underlying portions of the fins while the exposed portions of the fins are etched away as seen in FIG. 4B. According to some embodiments, both semiconductor layers 204 and sacrificial layers 202 are etched at substantially the same rate using an anisotropic reactive ion etching (RIE) process. As observed in FIG. 4B, the fins are completely removed above subfin regions 304. In some embodiments, the RIE process may also etch into subfin regions 304 thus recessing subfin regions 304 beneath a top surface of dielectric fill 306. In some embodiments, inner gate spacers can be formed after the source/drain trenches are etched and before any formation of source or drain regions. For instance, a selective etch can be used to laterally recess sacrificial layers 202, and that recess can then be filled with inner gate spacer material (e.g., silicon nitride or silicon oxynitride). Any excess gate spacer material can be removed with directional etching.

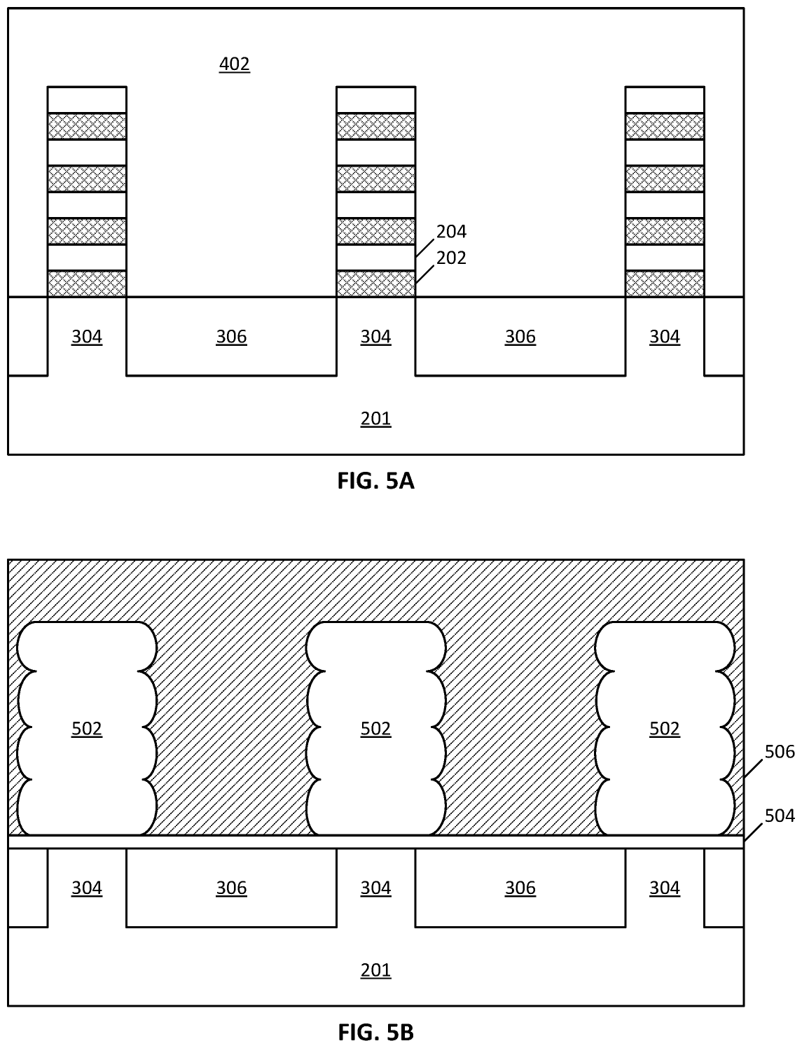

FIGS. 5A and 5B depict the cross-section views of the structure shown in FIGS. 4A and 4B, respectively, following the formation of source or drain regions 502 at the ends of each of the fins (extending into and out of the page in FIG. 5A), according to some embodiments. Source or drain regions 502 may be epitaxially grown from the exposed ends of semiconductor layers 204, such that the material grows together or otherwise merges towards the middle of the trenches between fins, according to some embodiments. Note that epitaxial growth on one semiconductor layer 204 can fully or partially merge with epitaxial growth on one or more other semiconductor layers 204 in the same vertical stack. The degree of any such merging can vary from one embodiment to the next. In the example of a PMOS device, a given source or drain region may be a semiconductor material (e.g., group IV or group III-V semiconductor materials) having a higher dopant concentration of p-type dopants compared to n-type dopants. In the example of an NMOS device, a given source or drain region may be a semiconductor material (e.g., group IV or group III-V semiconductor materials) having a higher dopant concentration of n-type dopants compared to p-type dopants. According to some embodiments, source or drain regions 502 grown from different semiconductor devices may be aligned along the source/drain trench in the second direction as shown in FIG. 5B.

According to some embodiments, a bottom dielectric layer 504 may be deposited prior to the formation of source or drain regions 502. Bottom dielectric layer 504 may be any suitable dielectric material, such as silicon dioxide, silicon nitride, or silicon oxynitride. Bottom dielectric layer 504 may be included to provide isolation between source or drain regions 502 and subfin regions 304.

According to some embodiments, another dielectric fill 506 is provided along the source/drain trench. Dielectric fill 506 may extend between adjacent ones of the source or drain regions 502 along the second direction and also may extend up and over each of the source or drain regions 502, according to some embodiments. Accordingly, each source or drain region may be isolated from any adjacent source or drain regions by dielectric fill 506. Dielectric fill 506 may be any suitable dielectric material, although in some embodiments, dielectric fill 506 includes the same dielectric material as dielectric fill 306 or bottom dielectric layer 504. In one example, each of dielectric fill 506, bottom dielectric layer 504, and dielectric fill 306 includes silicon dioxide. Dielectric fill 506 may not be present between certain adjacent source or drain regions in situations where the adjacent source or drain regions are desired to be electrically coupled together. According to some embodiments, a top surface of dielectric fill 506 may be polished using, for example, chemical mechanical polishing (CMP). The top surface of dielectric fill 506 may be polished until it is substantially coplanar with a top surface of sacrificial gate 402.

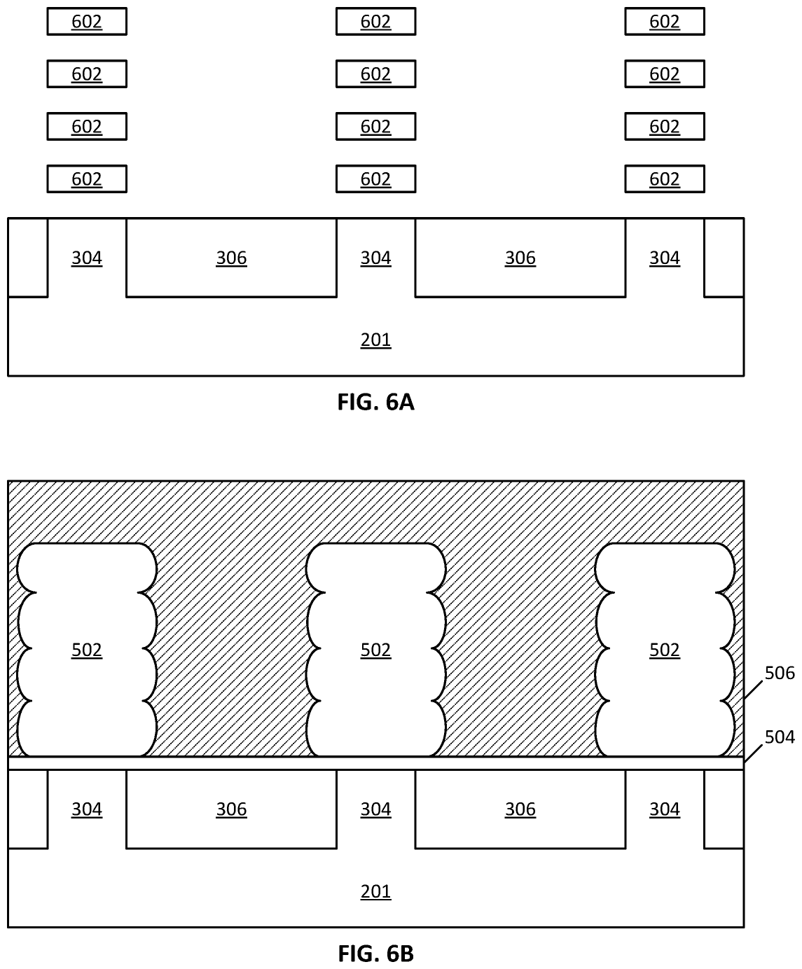

FIGS. 6A and 6B depict the cross-section views of the structure shown in FIGS. 5A and 5B, respectively, following the formation of nanoribbons 602 from semiconductor layers 204, according to some embodiments. Depending on the dimensions of the structures, nanoribbons 602 may also be considered nanowires or nanosheets. Sacrificial gate 402 may be removed using any wet or dry isotropic process thus exposing the alternating layer stack of the fins within the trenches left behind after the removal of sacrificial gate 402. Once sacrificial gate 402 is removed, sacrificial layers 202 may also be removed using a selective isotropic etching process that removes the material of sacrificial layers 202 but does not remove (or removes very little of) semiconductor layers 204 or any other exposed layers (e.g., inner gate spacers). At this point, the suspended (sometimes called released) semiconductor layers 204 form nanoribbons 602 that extend in the first direction (into and out of the page) between corresponding source or drain regions 502.

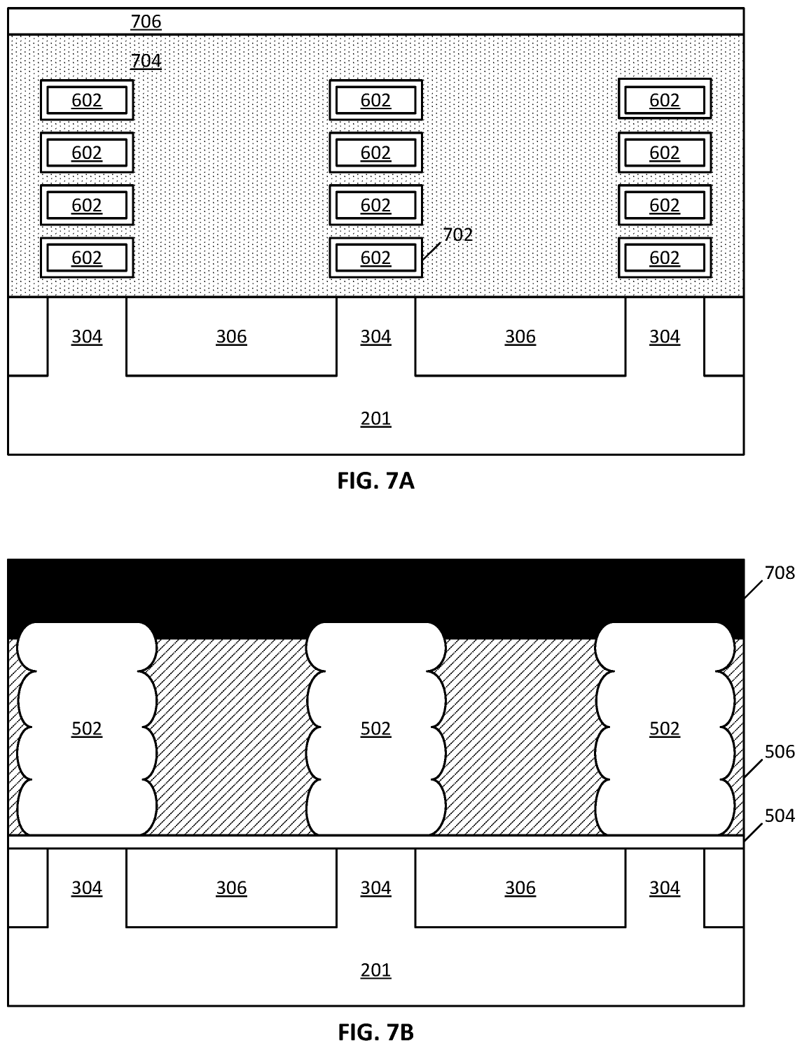

FIGS. 7A and 7B depict the cross-section views of the structure shown in FIGS. 6A and 6B, respectively, following the formation of a gate structure around nanoribbons 602 within the gate trench, according to some embodiments. As noted above, the gate structure includes a gate dielectric 702 and a gate electrode 704. Gate dielectric 702 may be conformally deposited around nanoribbons 602 using any suitable deposition process, such as atomic layer deposition (ALD). Gate dielectric 702 may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 702 is hafnium oxide with a thickness between about 1 nm and about 5 nm. In some embodiments, gate dielectric 702 may include one or more silicates (e.g., titanium silicate, tungsten silicate, niobium silicate, and silicates of other transition metals). Gate dielectric 702 may be a multilayer structure, in some examples. For instance, gate dielectric 702 may include a first layer on nanoribbons 602, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on gate dielectric 702 to improve its quality when a high-k dielectric material is used. In some embodiments, the high-k material can be nitridized to improve its aging resistance.

Gate electrode 704 may be deposited over gate dielectric 702 and can be any conductive structure. In some embodiments, gate electrode 704 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 704 may include, for instance, one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

According to some embodiments, a gate cap 706 may be formed by first recessing gate electrode 704 and filling the recess with a dielectric material. The dielectric material may then be polished such that its top surface is substantially coplanar with any adjacent spacer structures or material within the source/drain trench. Gate cap 706 may be any suitable dielectric material, such as silicon nitride.

According to some embodiments, a portion of dielectric fill 506 may be recessed within the source/drain trench to expose at least a top surface of source or drain regions 502. A conductive contact 708 may be formed within the recess to contact at least the top surfaces of source or drain regions 502. In some embodiments, dielectric fill 506 is recessed far enough to expose one or more side surfaces of source or drain regions 502, in which case conductive contact 708 also contacts the exposed side surfaces of source or drain regions 502. Conductive contact 708 may include any suitable conductive material, such as tungsten, molybdenum, or ruthenium, for making electrical contact with the underlying source or drain regions 502. A top surface of conductive contact 708 may be polished to be substantially coplanar with a top surface of gate cap 706.

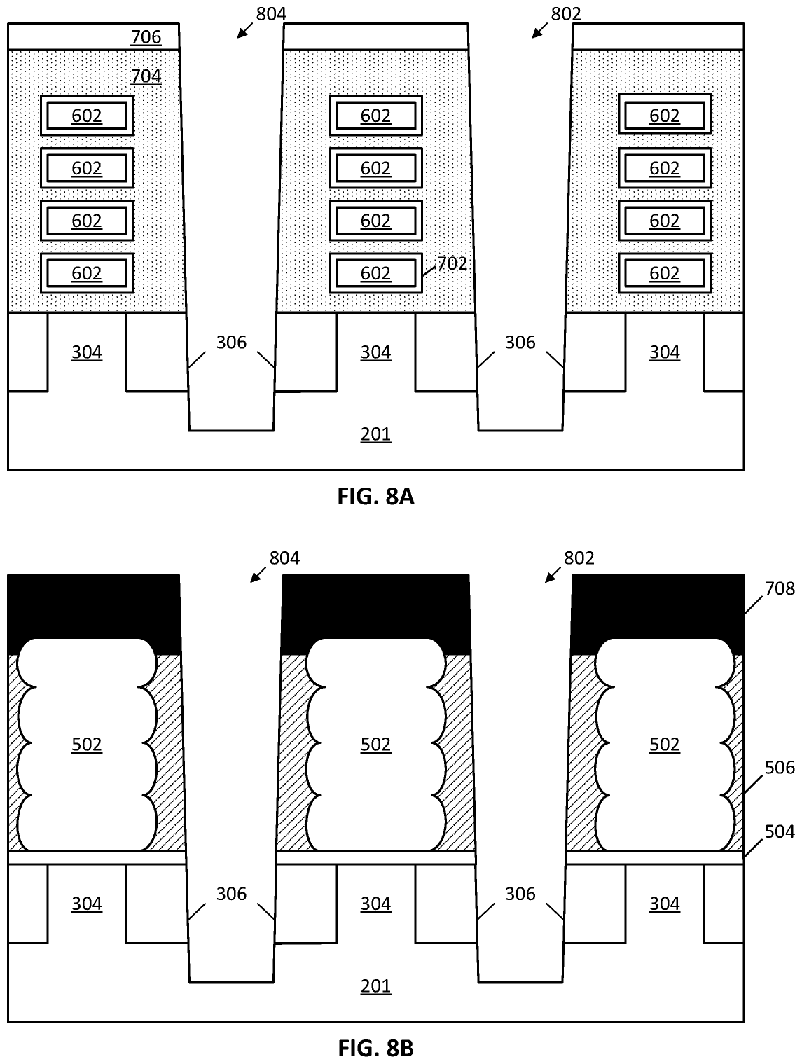

FIGS. 8A and 8B depict cross-section views of the structure shown in FIGS. 7A and 7B, respectively, following the formation of deep recesses 802 and 804, according to some embodiments. Each of deep recesses 802/804 extend to a depth at least through an entire thickness of the gate structures. Deep recesses 802/804 may further extend through an entire thickness of dielectric fill 306 and into a portion of substrate 201. In other embodiments, deep recesses 802/804 extend through only a portion of dielectric fill 306.

Deep recesses 802/804 may be formed by etching through gate electrode 704 using any suitable metal gate etch process that iteratively etches through portions of gate electrode 704 while simultaneously protecting the sidewalls of the recess from lateral etching to provide a high height-to-width aspect ratio recess (e.g., aspect ratio of 5:1 or higher, or 10:1 or higher). Deep recesses 802/804 may extend in the first direction through multiple gate trenches and source/drain trenches to isolate adjacent gate structures and source or drain regions. Accordingly, deep recesses 802/804 may extend in the first direction through the source/drain trench and separate adjacent source or drain regions 502 from one another. An anisotropic RIE process may be performed to etch through the various materials to form deep recesses 802/804.

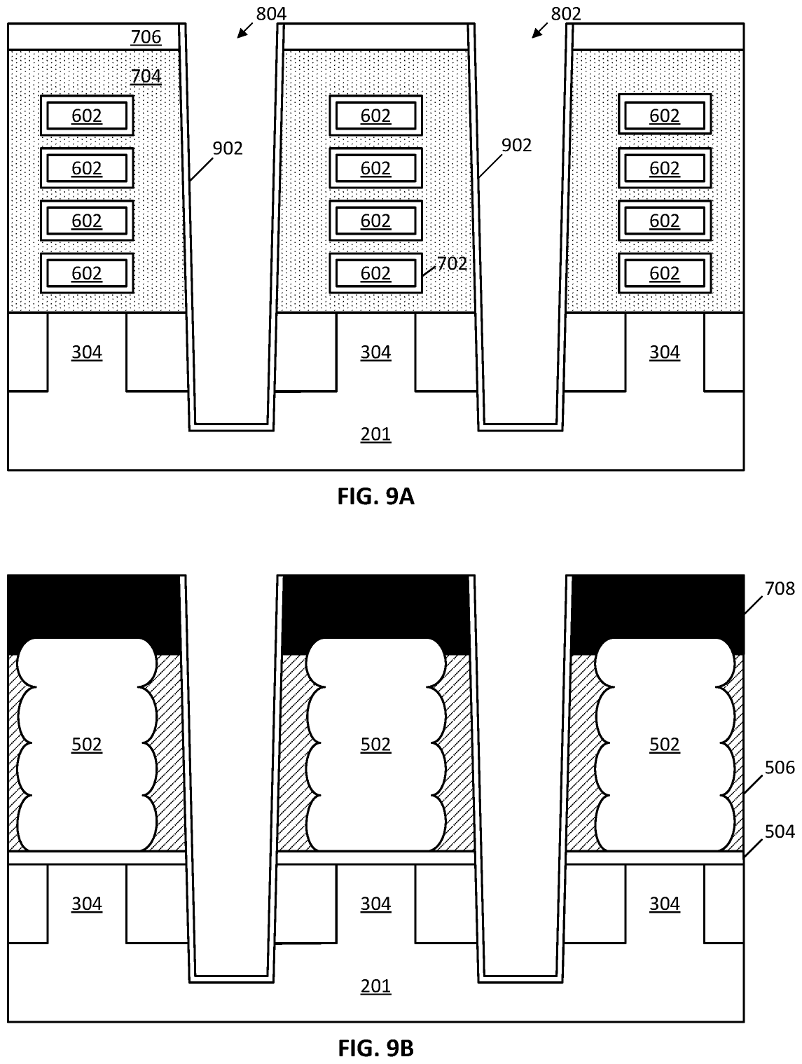

FIGS. 9A and 9B depict cross-section views of the structure shown in FIGS. 8A and 8B, respectively, following the formation of a sacrificial layer 902 along at least the sidewalls of deep recesses 802/804, according to some embodiments. Sacrificial layer 902 may also form on the bottom surface of deep recesses 802/804. According to some embodiments, sacrificial layer 902 includes a material that can be easily removed at a later time without damaging surrounding structures (such as gate electrode 704). In one example, sacrificial layer 902 includes aluminum oxide. Sacrificial layer 902 may have a thickness of less than 10 nm, such as between 5 nm and 7 nm.

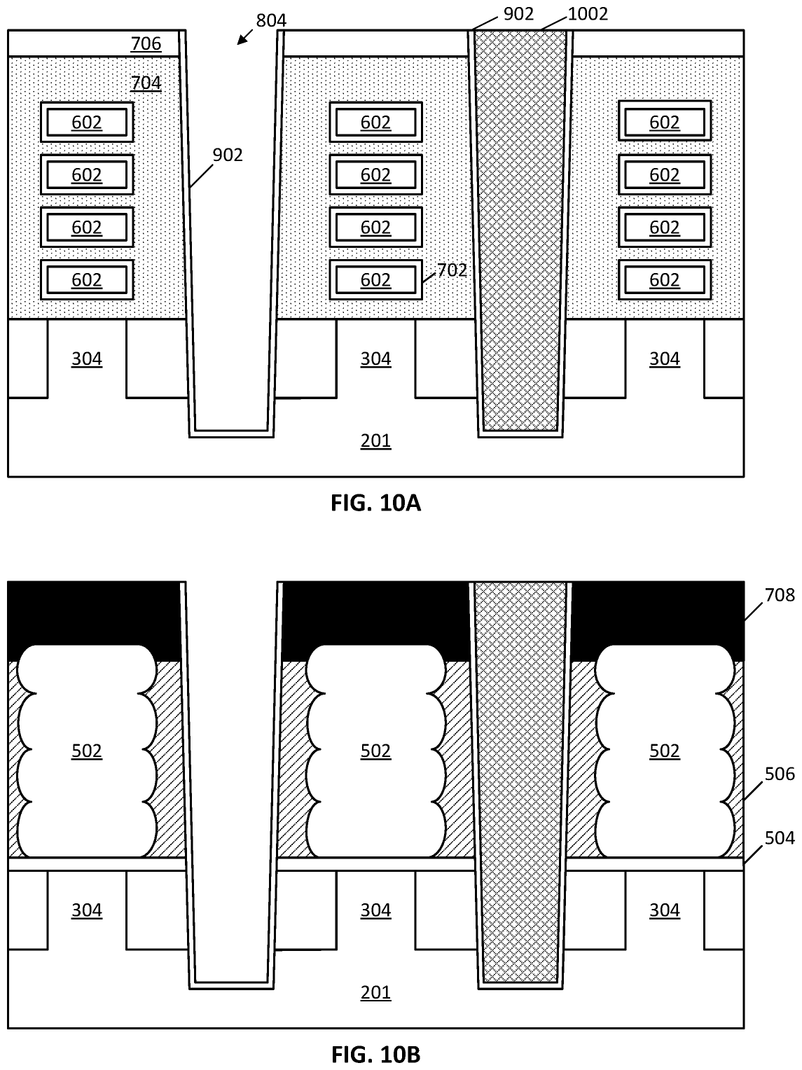

FIGS. 10A and 10B depict cross-section views of the structure shown in FIGS. 9A and 9B, respectively, following the formation of a sacrificial material 1002 within deep recess 802 while leaving deep recess 804 clear, according to some embodiments. Sacrificial material 1002 may be fully deposited within both deep recesses 802 and 804 and then selectively removed from deep recess 804 using any suitable lithography techniques. In one example, sacrificial material 1002 is carbon hard mask (CHM) and can be removed using an ashing process, or any other suitable isotropic etching process.

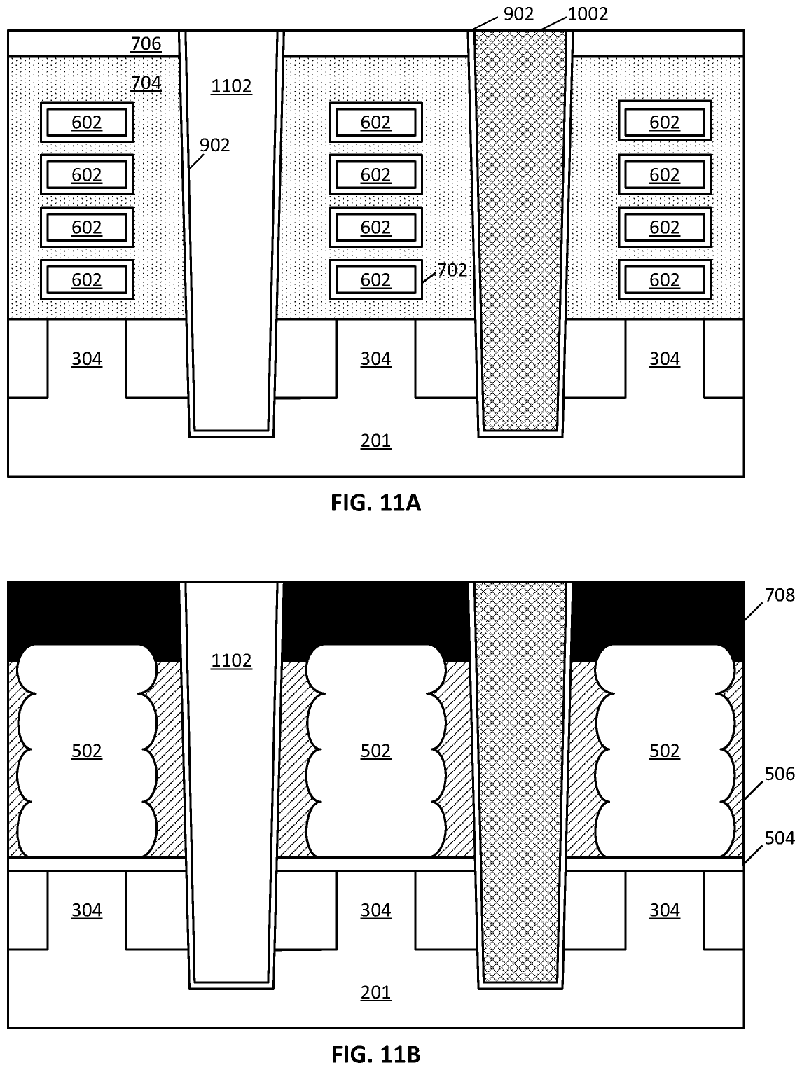

FIGS. 11A and 11B depict cross-section views of the structure shown in FIGS. 10A and 10B, respectively, following the formation of a dielectric structure 1102 within deep recess 804, according to some embodiments. Dielectric structure 1102 may represent a gate cut through gate electrode 704. According to some embodiments, dielectric structure 1102 includes one or more dielectric materials. In some examples, dielectric structure 1102 includes silicon nitride or silicon dioxide. In some examples, dielectric structure 1102 includes any suitable low-k dielectric material (e.g., a material having a dielectric constant of silicon dioxide or lower). One or more airgaps may exist within dielectric structure 1102 due to pinching off of the material as it forms near the top of the recess.

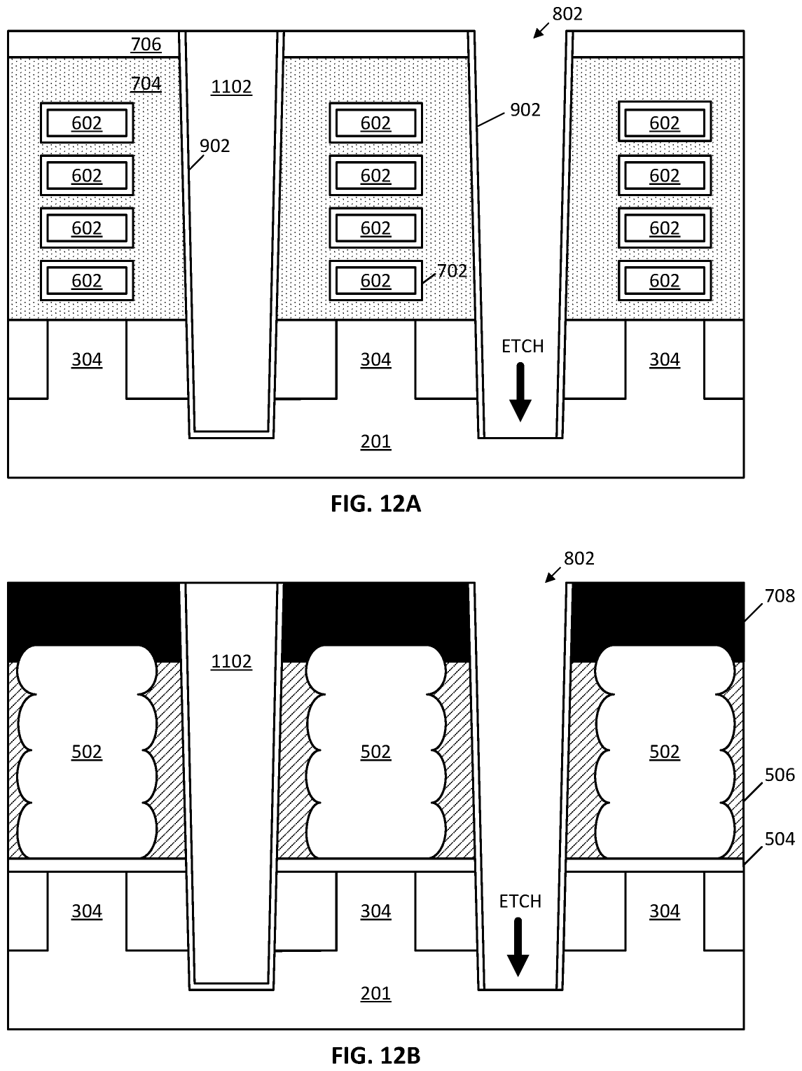

FIGS. 12A and 12B depict cross-section views of the structure shown in FIGS. 11A and 11B, respectively, following the removal of sacrificial material 1002 and subsequent removal of the bottom portion of sacrificial layer 902, according to some embodiments. As noted above, sacrificial material 1002 may be removed using an ashing process or any other suitable isotropic etching process. According to some embodiments, an anisotropic etching process may be used to punch through the bottom portion of sacrificial layer 902 within deep recess 802 while maintaining the sidewalls portions of sacrificial layer 902. The removal of the bottom portion of sacrificial layer 902 exposes substrate 201 at the bottom of deep recess 802.

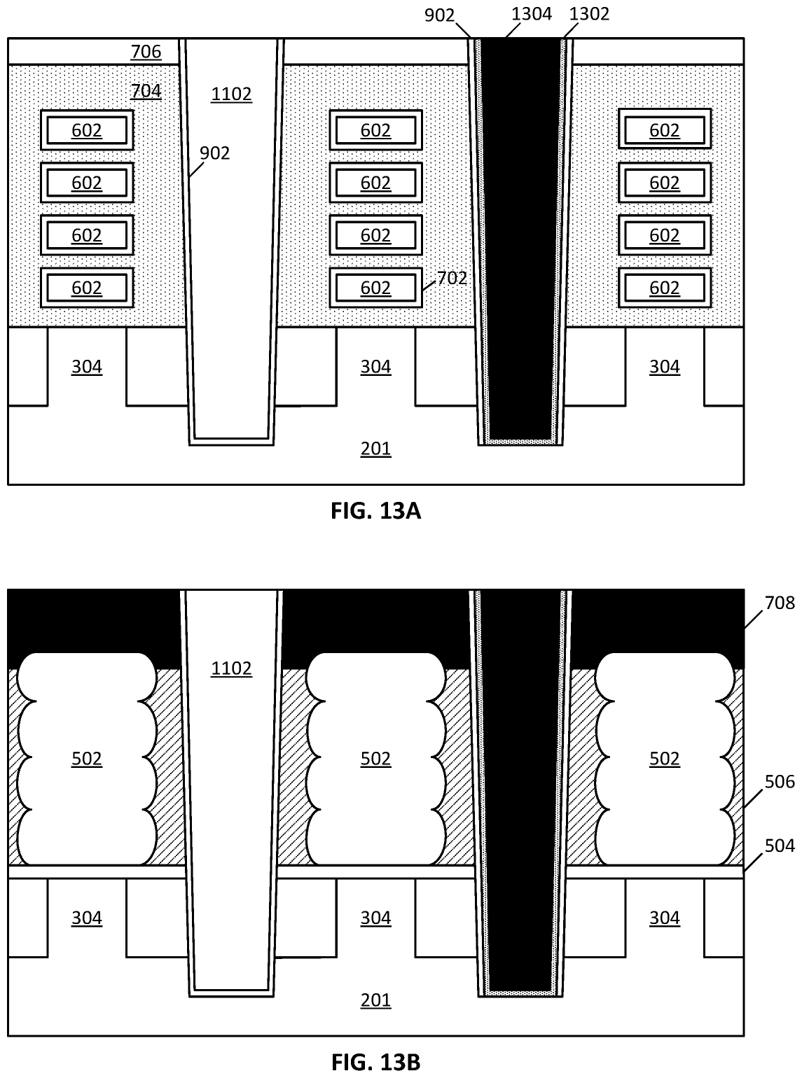

FIGS. 13A and 13B depict cross-section views of the structure shown in FIGS. 12A and 12B, respectively, following the formation of a conductive via within deep recess 802, according to some embodiments. The conductive via may include a conductive liner 1302 and a conductive fill 1304. Conductive liner 1302 may include any suitable material to act as an adhesion layer for conductive fill 1304. In some examples, conductive liner 1302 includes titanium nitride or tantalum nitride. Conductive fill 1304 may include any suitable conductive material, such as tungsten, ruthenium, molybdenum, or cobalt. Each of the conductive via and dielectric structure 1102 are examples of through-gate structures. Note that the conductive via contacts a portion of substrate 201 due to the removal of the bottom portion of sacrificial layer 902 within deep recess 802. The formation of the conductive via by depositing conductive materials within the remaining volume of deep recess 802 also self-aligns the conductive via within the center of deep recess 802. This self-alignment is helpful to avoid shorting between the conductive via and adjacent gate electrode 704, which can be caused by alignment error if using lithography to align the placement of the conductive via.

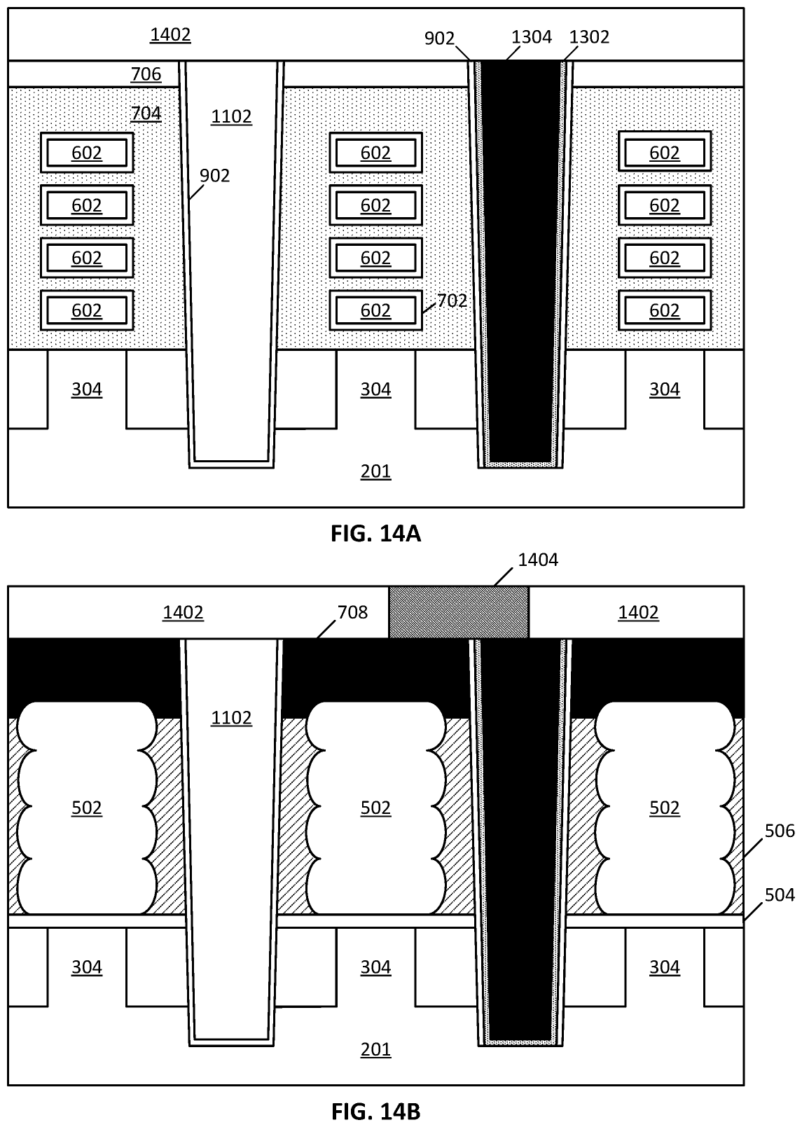

FIGS. 14A and 14B depict cross-section views of the structure shown in FIGS. 13A and 13B, respectively, following the formation of an interconnect layer above the semiconductor devices, according to some embodiments. The interconnect layer includes a dielectric interconnect layer 1402 and a conductive interconnect layer 1404. dielectric interconnect layer 1402 may include any suitable dielectric material, such as silicon dioxide. Conductive interconnect layer 1404 may include any suitable conductive material, such as tungsten, ruthenium, molybdenum, or cobalt. In some examples, conductive interconnect layer 1404 includes the same conductive material as conductive fill 1304. According to some embodiments, conductive interconnect layer 1404 contacts a top surface of both the conductive via (e.g., a top surface of conductive fill 1304) and the top surface of an adjacent conductive contact 708. The interconnect layer may be one interconnect layer of any number of stacked interconnect layers over the semiconductor devices that are formed during back-end-of-the-line (BEOL) processing.

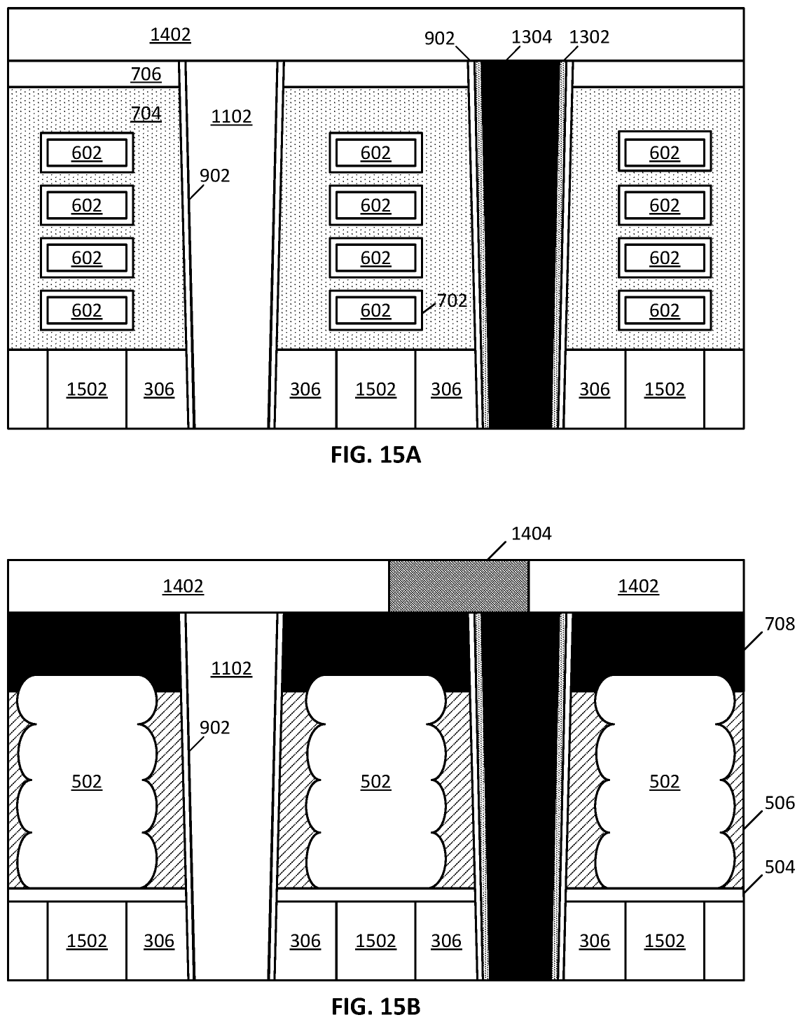

FIGS. 15A and 15B depict cross-section views of the structure shown in FIGS. 14A and 14B, respectively, following the removal of substrate 201 from the backside, according to some embodiments. Once all front-side processes have been performed across the integrated circuit, substrate 201 may be removed via any arrangement of grinding, polishing, and/or chemical etching processes. According to some embodiments, all materials are removed from the backside up until at least a bottom surface of dielectric fill 306 is exposed. Accordingly, a bottom portion of any of the through-gate structures (e.g., the conductive via and dielectric structure 1102) may be exposed on the backside as well. According to some embodiments, subfin regions 304 are also removed from the backside and replaced with dielectric material 1502, which may include any number of dielectric layers.

FIGS. 16A and 16B depict cross-section views of the structure shown in FIGS. 15A and 15B, respectively, following the removal of sacrificial layer 902 from the backside, according to some embodiments. Any suitable isotropic etching process may be used to selectively remove sacrificial layer 902. Removing sacrificial layer 902 from around the conductive via leaves behind first airgaps 1602 and removing sacrificial layer 902 from around dielectric structure 1102 leaves behind second airgaps 1604, according to some embodiments. The airgaps may extend along the entire height of each of the through-gate structures and separate each of the through-gate structures from any other structures along the second direction. For example, first airgaps 1602 are between the conductive via and electrode 704 and between the conductive via and dielectric fill 306 along the gate trench. First airgaps 1602 are also between the conductive via and conductive contacts 708 and between the conductive via and source or drain regions 502 along the source/drain trench. Similarly, second airgaps 1604 are between dielectric structure 1102 and electrode 704 and between dielectric structure 1102 and dielectric fill 306 along the gate trench. Second airgaps 1604 are also between dielectric structure 1102 and conductive contacts 708 and between dielectric structure 1102 and source or drain regions 502 along the source/drain trench.

First airgaps 1602 and second airgaps 1604 may have substantially the same thickness (e.g., less than 10 nm ) as they are formed from the removal of the same sacrificial layer 902. In some examples, the thickness of first airgaps 1602 and second airgaps 1604 is between about 5 nm and about 7 nm. According to some embodiments, the first interconnect layer spans across the top of first airgaps 1602 and second airgaps 1604. For example, conductive interconnect layer 1404 extends across the top of one of first airgaps 1602 to contact both the conductive via and conductive contact 708. A backside interconnect layer may also be formed that bridges across the bottom of first airgaps 1602 and/or second airgaps 1604. The airgaps provide a region of very low dielectric constant (around 1.0) between the conductive via and adjacent conductive structures (e.g., gate electrode 704 and contact 708), thus reducing the parasitic capacitance. It should be noted that first airgaps 1602 and second airgaps 1604 may include an inert gas (e.g., argon) or no appreciable gas at a vacuum pressure.

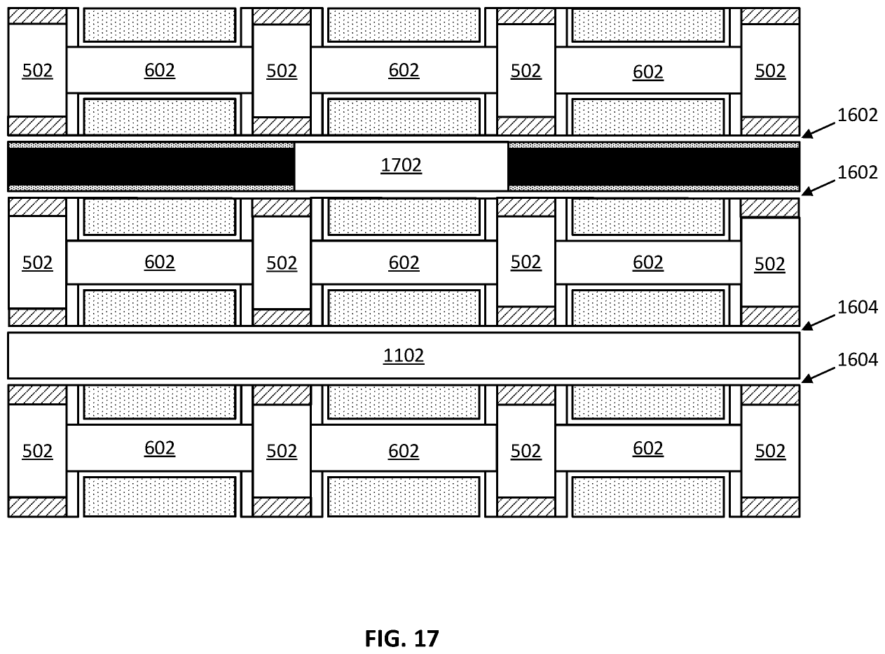

The conductive via may not extend through all gate trenches along the first direction. FIG. 17 illustrates an example plan view across an integrated circuit showing a dielectric plug 1702 present along a given conductive via track in the first direction, according to some embodiments. In this way, different conductive vias (e.g., electrically isolated from one another) can be formed within the same trench running in the first direction across multiple gate trenches. In the illustrated example, two conductive vias are formed colinearly to one another and separated by dielectric plug 1702. Dielectric plug 1702 may act similarly to a gate cut and may be substantially similar to dielectric structure 1102. Accordingly, dielectric plug 1702 may include any suitable dielectric material, such as silicon dioxide or silicon nitride. First airgaps 1602 flank the sidewalls of dielectric plug 1702 just as they do for the conductive via, according to some embodiments.

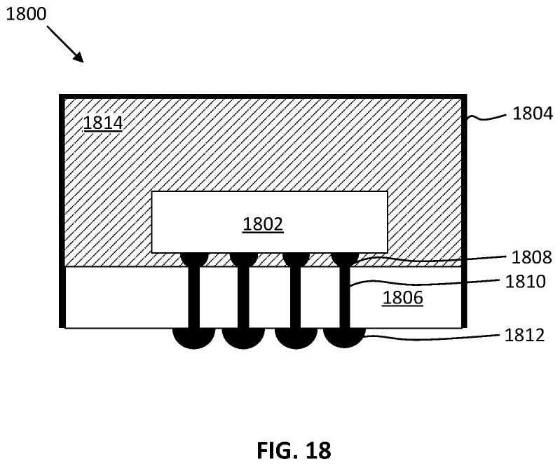

FIG. 18 illustrates an example embodiment of a chip package 1800, in accordance with an embodiment of the present disclosure. As can be seen, chip package 1800 includes one or more dies 1802. One or more dies 1802 may include at least one integrated circuit having semiconductor devices, such as any of the semiconductor devices disclosed herein. One or more dies 1802 may include any other circuitry used to interface with other devices formed on the dies, or other devices connected to chip package 1800, in some example configurations.

As can be further seen, chip package 1800 includes a housing 1804 that is bonded to a package substrate 1806. The housing 1804 may be any housing, and may provide, for example, electromagnetic shielding and environmental protection for the components of chip package 1800. The one or more dies 1802 may be conductively coupled to a package substrate 1806 using connections 1808, which may be implemented with any number of connection mechanisms, such as solder bumps, ball grid array (BGA), pins, or wire bonds, to name a few examples. Package substrate 1806 may be any package substrate, but in some cases includes a dielectric material having conductive pathways (e.g., including conductive vias and lines) extending through the dielectric material between the faces of package substrate 1806, or between different locations on each face. In some embodiments, package substrate 1806 may have a thickness less than 1 millimeter (e.g., between 0.1 millimeters and 0.5 millimeters), although any number of package geometries can be used. Additional conductive contacts 1812 may be disposed at an opposite face of package substrate 1806 for conductively contacting, for instance, a printed circuit board (PCB). One or more vias 1810 extend through a thickness of package substrate 1806 to provide conductive pathways between one or more of connections 1808 to one or more of contacts 1812. Vias 1810 are illustrated as single straight columns through package substrate 1806 for case of illustration, although other configurations can be used (e.g., damascene, dual damascene, through-silicon via, or an interconnect feature that meanders through the thickness of substrate 1806 to contact one or more intermediate locations therein). In still other embodiments, vias 1810 are fabricated by multiple smaller stacked vias, or are staggered at different locations across package substrate 1806. In the illustrated embodiment, contacts 1812 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1812, to inhibit shorting.

In some embodiments, a mold material 1814 may be disposed around the one or more dies 1802 included within housing 1804 (e.g., between dies 1802 and package substrate 1806 as an underfill material, as well as between dies 1802 and housing 1804 as an overfill material). Although the dimensions and qualities of the mold material 1814 can vary from one embodiment to the next, in some embodiments, a thickness of mold material 1814 is less than 1 millimeter. Example materials that may be used for mold material 1814 include epoxy mold materials, as suitable. In some cases, the mold material 1814 is thermally conductive, in addition to being electrically insulating.

### Methodology

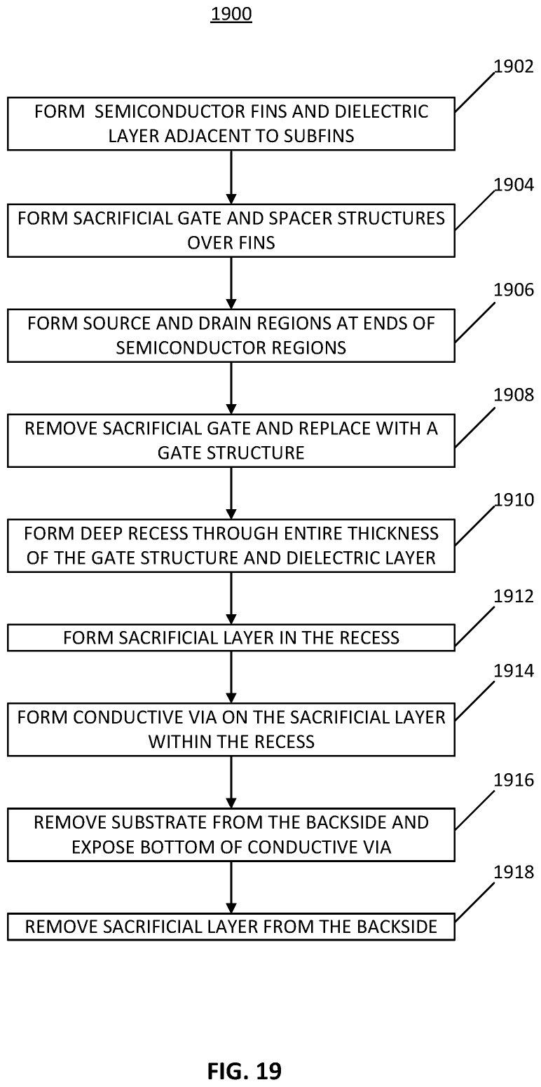

FIG. 19 is a flow chart of a method 1900 for forming at least a portion of an integrated circuit, according to an embodiment. Various operations of method 1900 may be illustrated in FIGS. 2A-16A and FIGS. 2B-16B. However, the correlation of the various operations of method 1900 to the specific components illustrated in the aforementioned figures is not intended to imply any structural and/or use limitations. Rather, the aforementioned figures provide example embodiments of method 1900. Other operations may be performed before, during, or after any of the operations of method 1900. For example, method 1900 does not explicitly describe all processes that are performed to form common transistor structures. Some of the operations of method 1900 may be performed in a different order than the illustrated order.

Method 1900 begins with operation 1902 where any number of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric layer is formed around subfin portions of the one or more fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 1900 continues with operation 1904 where a sacrificial gate and spacer structures are formed over the fins. The sacrificial gate may be patterned using a gate masking layer in a strip that runs orthogonally over the fins (many gate masking layers and corresponding sacrificial gates may be formed parallel to one another (e.g., forming a cross-hatch pattern with the fins). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 1900 continues with operation 1906 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). A dielectric fill may be formed around and over the tops of the source or drain regions along the source/drain trench. The dielectric fill may include any suitable dielectric material, such as silicon dioxide or silicon oxynitride.

Method 1900 continues with operation 1908 where the sacrificial gate is replaced with a gate structure. According to some embodiments, the sacrificial gate may be removed along with any sacrificial layers within the exposed fins between the spacer structures (in the case of GAA structures). A gate structure may then be formed in place of the sacrificial gate. The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

According to some embodiments, contacts are formed over the source or drain regions. The contacts may include any suitable conductive material, such as tungsten, molybdenum, ruthenium, or cobalt. The contact may include any number of different conductive materials and may extend over the top surfaces of any number of source or drain regions within the source/drain trench.

Method 1900 continues with operation 1910 where a deep recess is formed through at least an entire thickness of the gate structure. According to some embodiments, a trench recess may be etched through both the gate structure and through the dielectric fill around the source or drain regions, such that the trench recess extends along the first direction across both the gate trench and the source/drain trench. The trench recess may extend substantially parallel and lengthwise to the fins or nanowires. A reactive ion etching (RIE) process may be used to cut through the various material layers and form the trench. In some embodiments, the trench extends deep enough to extend through an entire thickness of the dielectric layer beneath the gate structure and expose the substrate beneath the dielectric layer.

Method 1900 continues with operation 1912 where a sacrificial layer is formed within the trench recess. According to some embodiments, the sacrificial layer is formed at least on the sidewalls of the trench recess and may also form on the bottom surface of the trench recess. The sacrificial layer may have a thickness of less than 10 nm , or between 5 and 7 nm. In some examples, the sacrificial layer includes aluminum oxide. The sacrificial layer may be formed using a conformal deposition process to produce a layer having substantially the same thickness on both trench recess sidewalls. An example conformal deposition process is ALD.

Method 1900 continues with operation 1914 where a conductive via is formed on the sacrificial layer within the trench recess. The conductive via may include any number of conductive layers. For example, the conductive via may include a conductive liner formed first on the sacrificial layer and a conductive fill formed on the conductive liner. In some examples, the conductive liner includes titanium nitride or tantalum nitride. The conductive fill may include any suitable conductive material, such as tungsten, ruthenium, molybdenum, or cobalt. The formation of the conductive via by depositing conductive materials within the remaining volume of the trench recess after forming the sacrificial layer also self-aligns the conductive via within the center of the trench recess (as the sacrificial layer has substantially the same thickness on both sidewalls owing to its conformal deposition process). This self-alignment is helpful to avoid shorting between the conductive via and the adjacent gate electrode.

Method 1900 continues with operation 1916 where the substrate is removed from the backside to expose at least a bottom surface of the conductive via. The substrate may be removed via any arrangement of grinding, polishing, and/or chemical etching processes. According to some embodiments, all materials are removed from the backside up until at least a bottom surface of the dielectric layer beneath the gate structure is exposed or until a bottom surface of the conductive via is exposed. According to some embodiments, the subfin portions may exposed from the backside and replaced with additional dielectric materials.

Method 1900 continues with operation 1918 where the sacrificial layer is removed from the backside (e.g., from exposing the backside of the structure to one or more etchants). Any suitable isotropic etching process may be used to selectively remove the sacrificial layer. Removing the sacrificial layer from around the conductive via leaves behind airgaps between the sidewalls of the conductive via and adjacent structures, according to some embodiments. The airgaps may extend along the entire height of the conductive via. For example, the airgaps are between the conductive via and the gate electrode and between the conductive via and the dielectric layer beneath the gate structure along the gate trench. The first airgaps may also be between the conductive via and the adjacent source or drain region and its contact along the source/drain trench.

### Example System

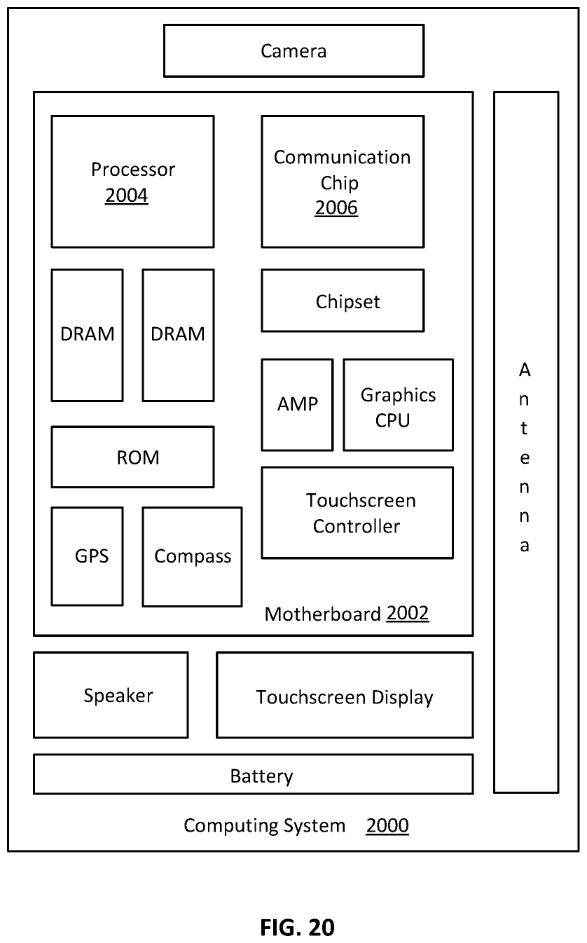

FIG. 20 is an example computing system implemented with one or more of the integrated circuit structures as disclosed herein, in accordance with some embodiments of the present disclosure. As can be seen, the computing system 2000 houses a motherboard 2002. The motherboard 2002 may include a number of components, including, but not limited to, a processor 2004 and at least one communication chip 2006, each of which can be physically and electrically coupled to the motherboard 2002, or otherwise integrated therein. As will be appreciated, the motherboard 2002 may be, for example, any printed circuit board (PCB), whether a main board, a daughterboard mounted on a main board, or the only board of system 2000, etc.

Depending on its applications, computing system 2000 may include one or more other components that may or may not be physically and electrically coupled to the motherboard 2002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2000 may include one or more integrated circuit structures or devices configured in accordance with an example embodiment (e.g., a module including an integrated circuit on a substrate, the substrate having semiconductor devices that include through-gate structures with airgap spacers). In some embodiments, multiple functions can be integrated into one or more chips (e.g., for instance, note that the communication chip 2006 can be part of or otherwise integrated into the processor 2004).

The communication chip 2006 enables wireless communications for the transfer of data to and from the computing system 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

The processor 2004 of the computing system 2000 includes an integrated circuit die packaged within the processor 2004. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 2006 also may include an integrated circuit die packaged within the communication chip 2006. In accordance with some such example embodiments, the integrated circuit die of the communication chip includes one or more semiconductor devices as variously described herein. As will be appreciated in light of this disclosure, note that multi-standard wireless capability may be integrated directly into the processor 2004 (e.g., where functionality of any chips 2006 is integrated into processor 2004, rather than having separate communication chips). Further note that processor 2004 may be a chip set having such wireless capability. In short, any number of processor 2004 and/or communication chips 2006 can be used. Likewise, any one chip or chip set can have multiple functions integrated therein.

In various implementations, the computing system 2000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 2000 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a semiconductor region extending in a first direction from a source or drain region and a gate structure extending in a second direction over the semiconductor region, a dielectric layer beneath the gate structure, and a structure spaced from the semiconductor region in the second direction and extending in a third direction along an entire thickness of the gate structure and along an entire thickness of the dielectric layer. An airgap exists between the structure and the gate structure and between the structure and the dielectric layer.

Example 2 includes the integrated circuit of Example 1, wherein the structure comprises a dielectric material.

Example 3 includes the integrated circuit of Example 2, wherein the dielectric material comprises a low-k dielectric material.

Example 4 includes the integrated circuit of any one of Examples 1-3, wherein the structure comprises a conductive material.

Example 5 includes the integrated circuit of Example 4, wherein the conductive material comprises a conductive liner and a conductive fill on the conductive liner.

Example 6 includes the integrated circuit of Example 5, wherein the conductive liner comprises titanium and nitrogen.

Example 7 includes the integrated circuit of Example 5 or 6, wherein the conductive fill comprises tungsten, cobalt, ruthenium, or molybdenum.

Example 8 includes the integrated circuit of any one of Examples 1-7, wherein the airgap has a thickness of less than 10 nm.

Example 9 includes the integrated circuit of any one of Examples 1-8, wherein the semiconductor device is a first semiconductor device, the semiconductor region is a first semiconductor region, the source or drain region is a first source or drain region, the gate structure is a first gate structure, and the airgap is a first airgap. The integrated circuit further comprises a second semiconductor device having a second semiconductor region extending in the first direction from a second source or drain region, and a second gate structure extending in the second direction over the second semiconductor region. The structure is spaced from the second semiconductor region in the second direction such that the structure is between the first semiconductor region and the second semiconductor region along the second direction. A second airgap exists between the structure and the second gate structure.

Example 10 includes the integrated circuit of Example 9, wherein the first airgap and the second airgap have substantially the same thickness.

Example 11 includes the integrated circuit of any one of Examples 1-10, wherein the dielectric layer is a first dielectric layer, the integrated circuit further comprising a second dielectric layer over the gate structure, such that a top surface of the structure contacts a bottom surface of the second dielectric layer.

Example 12 includes the integrated circuit of Example 11, wherein the second dielectric layer extends over the airgap.

Example 13 includes the integrated circuit of any one of Examples 1-12, wherein the structure extends in the first direction adjacent to the source or drain region.

Example 14 includes the integrated circuit of Example 13, wherein the airgap also extends in the first direction such that the airgap is between the structure and the source or drain region.

Example 15 is a printed circuit board comprising the integrated circuit of any one of Examples 1-14.

Example 16 is an electronic device that includes a chip package having one or more dies. At least one of the one or more dies includes a semiconductor region extending in a first direction from a first source or drain region to a second source or drain region, a gate structure extending in a second direction over the semiconductor region, a dielectric layer beneath the gate structure, and a structure spaced from the semiconductor region in the second direction and extending in a third direction along an entire thickness of the gate structure and along an entire thickness of the dielectric layer. An airgap exists between the structure and the gate structure and between the structure and the dielectric layer.

Example 17 includes the electronic device of Example 16, wherein the structure comprises a dielectric material.

Example 18 includes the electronic device of Example 17, wherein the dielectric material comprises a low-k dielectric material.

Example 19 includes the electronic device of any one of Examples 16-18, wherein the structure comprises a conductive material.

Example 20 includes the electronic device of Example 19, wherein the conductive material comprises a conductive liner and a conductive fill on the conductive liner.

Example 21 includes the electronic device of Example 20, wherein the conductive liner comprises titanium and nitrogen.

Example 22 includes the electronic device of Example 20 or 21, wherein the conductive fill comprises tungsten, cobalt, ruthenium, or molybdenum.

Example 23 includes the electronic device of any one of Examples 16-22, wherein the airgap has a thickness of less than 10 nm.

Example 24 includes the electronic device of any one of Examples 16-23, wherein the semiconductor region is a first semiconductor region, the source or drain region is a first source or drain region, the gate structure is a first gate structure, and the airgap is a first airgap. The at least one of the one or more dies further comprises a second semiconductor device having a second semiconductor region extending in the first direction from a second source or drain region, and a second gate structure extending in the second direction over the second semiconductor region. The structure is spaced from the second semiconductor region in the second direction such that the structure is between the first semiconductor region and the second semiconductor region along the second direction. A second airgap exists between the structure and the second gate structure.

Example 25 includes the electronic device of Example 24, wherein the first airgap and the second airgap have substantially the same thickness.

Example 26 includes the electronic device of any one of Examples 16-25, wherein the dielectric layer is a first dielectric layer, the at least one of the one or more dies further comprising a second dielectric layer over the gate structure, such that a top surface of the structure contacts a bottom surface of the second dielectric layer.

Example 27 includes the electronic device of Example 26, wherein the second dielectric layer extends over the airgap.

Example 28 includes the electronic device of any one of Examples 16-27, wherein the structure extends in the first direction adjacent to the source or drain region.

Example 29 includes the electronic device of Example 28, wherein the airgap also extends in the first direction such that the airgap is between the structure and the source or drain region.

Example 30 includes the electronic device of any one of Examples 16-29, further comprising a printed circuit board, wherein the chip package is coupled to the printed circuit board.

Example 31 is a method of forming an integrated circuit. The method includes forming a fin comprising semiconductor material, the fin extending above a substrate and extending in a first direction; forming a dielectric layer adjacent to a subfin portion of the fin; forming source or drain regions at opposite ends of the fin; forming a gate structure on the dielectric layer and over the semiconductor material and extending in a second direction; forming a recess through an entire thickness of the gate structure and through an entire thickness of the dielectric layer; forming a sacrificial layer along sidewalls and a bottom surface of the recess; forming a conductive material on the sacrificial layer within the recess; removing the substrate from the backside of the integrated circuit, wherein the removing exposes a bottom surface of the conductive material; and removing the sacrificial layer from the backside to form an airgap between the conductive material and the gate structure and between the conductive material and the dielectric layer.

Example 32 includes the method of Example 31, wherein the sacrificial layer comprises aluminum and oxygen.

Example 33 includes the method of Example 31 or 32, wherein removing the sacrificial layer comprises applying an ammonia gas to etch the sacrificial layer.

Example 34 includes the method of any one of Examples 31-33, wherein forming the conductive material comprises forming a conductive liner and forming a conductive fill on the conductive liner.

Example 35 includes the method of any one of Examples 31-34, further comprising removing a bottom portion of the sacrificial layer prior to forming the conductive material.

Example 36 includes the method of any one of Examples 31-35, wherein the dielectric layer is a first dielectric layer, the method further comprising forming a second dielectric layer on a top surface of the conductive material prior to removing the sacrificial layer.

Example 37 is an integrated circuit that includes a semiconductor device having a semiconductor region extending in a first direction from a source or drain region, and a gate structure extending in a second direction over the semiconductor region, a first dielectric layer beneath the gate structure, a conductive structure spaced from the semiconductor region in the second direction and extending in a third direction along an entire thickness of the gate structure and along an entire thickness of the dielectric layer, and a second dielectric layer over the gate structure and on a top surface of the conductive structure. An airgap exists between the conductive structure and the gate structure and between the conductive structure and the dielectric layer.

Example 38 includes the integrated circuit of Example 37, wherein the conductive structure comprises a conductive liner and a conductive fill on the conductive liner.

Example 39 includes the integrated circuit of Example 38, wherein the conductive liner comprises titanium and nitrogen.

Example 40 includes the integrated circuit of Example 38 or 39, wherein the conductive fill comprises tungsten, cobalt, ruthenium, or molybdenum.

Example 41 includes the integrated circuit of any one of Examples 37-40, wherein the airgap has a thickness of less than 10 nm.

Example 42 includes the integrated circuit of any one of Examples 37-41, wherein the semiconductor device is a first semiconductor device, the semiconductor region is a first semiconductor region, the source or drain region is a first source or drain region, the gate structure is a first gate structure, and the airgap is a first airgap. The integrated circuit further comprises a second semiconductor device having a second semiconductor region extending in the first direction from a second source or drain region, and a second gate structure extending in the second direction over the second semiconductor region. The conductive structure is spaced from the second semiconductor region in the second direction such that the conductive structure is between the first semiconductor region and the second semiconductor region along the second direction. A second airgap exists between the conductive structure and the second gate structure.

Example 43 includes the integrated circuit of Example 42, wherein the first airgap and the second airgap have substantially the same thickness.

Example 44 includes the integrated circuit of any one of Examples 37-43, wherein the second dielectric layer extends over the airgap.

Example 45 includes the integrated circuit of any one of Examples 37-44, wherein the conductive structure extends in the first direction adjacent to the source or drain region.

Example 46 includes the integrated circuit of Example 45, wherein the airgap also extends in the first direction such that the airgap is between the conductive structure and the source or drain region.

Example 47 is a printed circuit board comprising the integrated circuit of any one of Examples 37-46.

Example 48 includes the subject matter of any one of Examples 1 through 47, wherein the semiconductor region (or first and second semiconductor regions) comprises one or more semiconductor nanoribbons, nanowires, or nanosheets. In another such example, the semiconductor region(s) comprises a semiconductor fin. In another such example, a first semiconductor region comprises one or more semiconductor nanoribbons, nanowires, or nanosheets, and a second semiconductor region comprises a fin.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a source or drain region, and a gate structure extending in a second direction over the semiconductor region;
a dielectric layer beneath the gate structure; and
a structure spaced from the semiconductor region in the second direction and extending in a third direction along an entire thickness of the gate structure and along an entire thickness of the dielectric layer, wherein an airgap exists between the structure and the gate structure and between the structure and the dielectric layer.

2. The integrated circuit of claim 1, wherein the structure comprises a dielectric material.

3. The integrated circuit of claim 1, wherein the structure comprises a conductive material.

4. The integrated circuit of claim 3, wherein the conductive material comprises a conductive liner and a conductive fill on the conductive liner.

5. The integrated circuit of claim 1, wherein the airgap has a thickness of less than 10 nm.

6. The integrated circuit of claim 1, wherein the semiconductor device is a first semiconductor device, the semiconductor region is a first semiconductor region, the source or drain region is a first source or drain region, the gate structure is a first gate structure, and the airgap is a first airgap, the integrated circuit further comprising:
a second semiconductor device having a second semiconductor region extending in the first direction from a second source or drain region, and a second gate structure extending in the second direction over the second semiconductor region,
wherein the structure is spaced from the second semiconductor region in the second direction such that the structure is between the first semiconductor region and the second semiconductor region along the second direction, wherein a second airgap exists between the structure and the second gate structure.

7. The integrated circuit of claim 1, wherein the dielectric layer is a first dielectric layer, the integrated circuit further comprising a second dielectric layer over the gate structure, such that a top surface of the structure contacts a bottom surface of the second dielectric layer.

8. The integrated circuit of claim 1, wherein the structure extends in the first direction adjacent to the source or drain region.

9. The integrated circuit of claim 8, wherein the airgap also extends in the first direction such that the airgap is between the structure and the source or drain region.

10. A printed circuit board comprising the integrated circuit of claim 1.

11. An electronic device, comprising:
a chip package comprising one or more dies, at least one of the one or more dies comprising
a semiconductor region extending in a first direction from a first source or drain region to a second source or drain region;
a gate structure extending in a second direction over the semiconductor region;
a dielectric layer beneath the gate structure; and
a structure spaced from the semiconductor region in the second direction and extending in a third direction along an entire thickness of the gate structure and along an entire thickness of the dielectric layer, wherein an airgap exists between the structure and the gate structure and between the structure and the dielectric layer.

12. The electronic device of claim 11, wherein the structure comprises a dielectric material.

13. The electronic device of claim 11, wherein the structure comprises a conductive material.

14. The electronic device of claim 11, wherein the semiconductor region is a first semiconductor region, the source or drain region is a first source or drain region, the gate structure is a first gate structure, and the airgap is a first airgap, the at least one of the one or more dies further comprising:
a second semiconductor device having a second semiconductor region extending in the first direction from a second source or drain region, and a second gate structure extending in the second direction over the second semiconductor region,
wherein the structure is spaced from the second semiconductor region in the second direction such that the structure is between the first semiconductor region and the second semiconductor region along the second direction, wherein a second airgap exists between the structure and the second gate structure.

15. The electronic device of claim 14, wherein the first airgap and the second airgap have substantially the same thickness.

16. An integrated circuit comprising:
a semiconductor device having a semiconductor region extending in a first direction from a source or drain region, and a gate structure extending in a second direction over the semiconductor region;
a first dielectric layer beneath the gate structure;
a conductive structure spaced from the semiconductor region in the second direction and extending in a third direction along an entire thickness of the gate structure and along an entire thickness of the dielectric layer, wherein an airgap exists between the conductive structure and the gate structure and between the conductive structure and the first dielectric layer; and
a second dielectric layer over the gate structure and on a top surface of the conductive structure.

17. The integrated circuit of claim 16, wherein the conductive structure comprises a conductive liner and a conductive fill on the conductive liner.

18. The integrated circuit of claim 16, wherein the semiconductor device is a first semiconductor device, the semiconductor region is a first semiconductor region, the source or drain region is a first source or drain region, the gate structure is a first gate structure, and the airgap is a first airgap, the integrated circuit further comprising:
a second semiconductor device having a second semiconductor region extending in the first direction from a second source or drain region, and a second gate structure extending in the second direction over the second semiconductor region,
wherein the conductive structure is spaced from the second semiconductor region in the second direction such that the conductive structure is between the first semiconductor region and the second semiconductor region along the second direction, wherein a second airgap exists between the conductive structure and the second gate structure.

19. The integrated circuit of claim 16, wherein the conductive structure extends in the first direction adjacent to the source or drain region.

20. The integrated circuit of claim 19, wherein the airgap also extends in the first direction such that the airgap is between the conductive structure and the source or drain region.
